(19) United States
(12) Patent Application Publication
(10) Pub. No.: US 2024/0195366 A1
(43) Pub. Date: Jun. 13, 2024

(54) AMPLIFIER CIRCUIT AND RADIO-FREQUENCY CIRCUIT

(71) Applicant: Murata Manufacturing Co., Ltd., Nagaokakyo-shi (JP)

(72) Inventors: Isao TAKENAKA, Nagaokakyo-shi (JP); Hisanori NAMIE, Nagaokakyo-shi (JP)

(73) Assignee: Murata Manufacturing Co., Ltd., Nagaokakyo-shi (JP)

(21) Appl. No.: 18/528,819

(22) Filed: Dec. 5, 2023

(30) Foreign Application Priority Data
Dec. 9, 2022 (JP) 2022-196703
Feb. 16, 2023 (JP) 2023-022860

(51) Int. Cl. H03F 3/195; H03F 1/56; H03F 3/21; H03F 3/213

(52) U.S. Cl. CPC H03F 3/195; H03F 1/565; H03F 3/211; H03F 3/213; H03F 2200/451; H03F 2200/48

(57) ABSTRACT

An amplifier circuit includes an inductor coupled to an amplifier, an inductor coupled to an amplifier, an inductor provided in series in a first output path connecting the amplifier and the inductor, a capacitor coupled to the first output path and the ground, a capacitor provided in series in a second output path connecting the amplifier and the inductor, an inductor coupled to the second output path and the ground, and a first circuit coupled between a first path connecting the inductors and a second path connecting the capacitor and the inductor.

### CROSS-REFERENCE TO RELATED APPLICATIONS

This application claims priority to Japanese Patent Application No. JP 2022-196703 filed on Dec. 9, 2022, and Japanese Patent Application No. JP 2023-022860 filed on Feb. 16, 2023. The entire contents of the above-identified applications, including the specifications, drawings and claims, are incorporated herein by reference in their entirety.

### BACKGROUND OF THE DISCLOSURE

### 1. Field of the Disclosure

The present disclosure relates to an amplifier circuit and a radio-frequency circuit.

### 2. Description of the Related Art

Japanese Unexamined Patent Application Publication No. 2012-147352 discloses a semiconductor device (an amplifier circuit) including a first amplifier and a second amplifier that constitute a balanced amplifier, a first phase shifter circuit provided in a first output path that connects an output end of the first amplifier and an output terminal, a second phase shifter circuit provided in a second output path that connects an output end of the second amplifier and the output terminal, a resistor coupled to an output end of the first phase shifter circuit and an output end of a second phase shifter circuit, a first inductor coupled between the output end of the first phase shifter circuit and the output terminal, and a second inductor coupled between the output end of the second phase shifter circuit and the output terminal. It is explained that this configuration reduces power combining losses in a power coupler constituted by the resistor, the first inductor, and the second inductor.

### SUMMARY OF THE DISCLOSURE

Due to the demands for high power performance of mobile phones, there is a need for highly efficient amplifier circuits.

The present disclosure has been made to solve the problem described above, and an object thereof is to provide an amplifier circuit and a radio-frequency circuit with highly efficient amplification characteristics.

To achieve the object described above, an amplifier circuit according to an aspect of the present disclosure includes a first amplifier and a second amplifier, an output terminal, a first phase shifter circuit coupled between an output end of the first amplifier and the output terminal, a second phase shifter circuit coupled between an output end of the second amplifier and the output terminal, a first inductor provided in series in a first output path connecting the output end of the first amplifier and the first phase shifter circuit, a first capacitor coupled between the first output path and ground, a second capacitor provided in series in a second output path connecting the output end of the second amplifier and the second phase shifter circuit, a second inductor coupled between the second output path and ground, and a first circuit coupled between a first path connecting the first inductor and the first phase shifter circuit and a second path connecting the second capacitor and the second phase shifter circuit. The first circuit includes a first resistor having one end configured to be coupled to the first path and another end configured to be coupled to the second path and a first switch configured to selectively couple the first path and the second path to each other via the first resistor or without using the first resistor.

An amplifier circuit according to an aspect of the present disclosure includes a first amplifier and a second amplifier, an output terminal, a first phase shifter circuit coupled between an output end of the first amplifier and the output terminal, a second phase shifter circuit coupled between an output end of the second amplifier and the output terminal, a third phase shifter circuit coupled to the output end of the first amplifier and the first phase shifter circuit, the third phase shifter circuit being configured to introduce a phase shift of a first phase amount to a radio-frequency signal, a fourth phase shifter circuit coupled to the output end of the second amplifier and the second phase shifter circuit, the fourth phase shifter circuit being configured to introduce a phase shift of a second phase amount to a radio-frequency signal, the second phase amount being different from the first phase amount by 90°, and a first circuit coupled between a first path connecting the third phase shifter circuit and the first phase shifter circuit and a second path connecting the fourth phase shifter circuit and the second phase shifter circuit. The first circuit includes a first resistor having one end configured to be coupled to the first path and another end configured to be coupled to the second path and a first switch configured to selectively couple the first path and the second path to each other via the first resistor or without using the first resistor.

An amplifier circuit according to an aspect of the present disclosure includes a carrier amplifier and a peak amplifier, an output terminal, a first phase shifter circuit coupled between an output end of the carrier amplifier and the output terminal, a second phase shifter circuit coupled between an output end of the peak amplifier and the output terminal, a first inductor provided in series in a first output path connecting the output end of the carrier amplifier and the first phase shifter circuit, a first capacitor coupled between the first output path and ground, a second capacitor provided in series in a second output path connecting the output end of the peak amplifier and the second phase shifter circuit, and a second inductor coupled between the second output path and ground. The first phase shifter circuit includes a third inductor. The second phase shifter circuit includes a fourth inductor.

An amplifier circuit according to an aspect of the present disclosure includes a carrier amplifier and a peak amplifier, an output terminal, a first phase shifter circuit coupled between an output end of the carrier amplifier and the output terminal, a second phase shifter circuit coupled between an output end of the peak amplifier and the output terminal, a fourth phase shifter circuit coupled to the output end of the carrier amplifier and the first phase shifter circuit, the fourth phase shifter circuit being configured to introduce a phase shift of a fourth phase amount to a radio-frequency signal, and a fifth phase shifter circuit coupled to the output end of the peak amplifier and the second phase shifter circuit, the fifth phase shifter circuit being configured to introduce a phase shift of a fifth phase amount to a radio-frequency signal, the fifth phase amount being different from the fourth phase amount by 90°. The first phase shifter circuit is configured to have the same phase rotation amount as the second phase shifter circuit.

The present disclosure provides an amplifier circuit and a radio-frequency circuit with highly efficient amplification characteristics.

### BRIEF DESCRIPTION OF THE DRAWINGS

FIG. 1 is a circuit configuration diagram of an amplifier circuit, a radio-frequency circuit, and a communication device according to a first embodiment;

FIG. 2 is a circuit configuration diagram of an amplifier circuit according to a first comparative example;

FIG. 3A is a circuit state diagram of the amplifier circuit according to the first embodiment in a first mode;

FIG. 3B is a circuit state diagram of the amplifier circuit according to the first embodiment in a second mode;

FIG. 4 is a flowchart illustrating an amplification method by the amplifier circuit according to the first embodiment;

FIG. 5 is a circuit configuration diagram of an amplifier circuit according to a first modification of the first embodiment;

FIG. 6 illustrates load impedance, supply current, gain, and power-added efficiency in a first mode, a second mode, and a third mode of the amplifier circuit according to the first modification of the first embodiment;

FIG. 7 illustrates load impedance, supply current, gain, and power-added efficiency in a low power mode of the amplifier circuit according to the first modification of the first embodiment;

FIG. 8 is a circuit configuration diagram of an amplifier circuit according to a second modification of the first embodiment;

FIG. 9 provides plan and sectional views of a radio-frequency circuit according to the first modification of the first embodiment;

FIG. 10 is a circuit configuration diagram of an amplifier circuit, a radio-frequency circuit, and a communication device according to a second embodiment;

FIG. 11 is a circuit configuration diagram of an amplifier circuit according to a second comparative example;

FIG. 12A is a circuit state diagram of the amplifier circuit according to the second embodiment at low input power;

FIG. 12B is a circuit state diagram of the amplifier circuit according to the second embodiment at high input power;

FIG. 13 is a circuit configuration diagram of an amplifier circuit according to a first modification of the second embodiment;

FIG. 14A is a circuit state diagram of the amplifier circuit according to the first modification of the second embodiment at low input power;

FIG. 14B is a circuit state diagram of the amplifier circuit according to the first modification of the second embodiment at high input power;

FIG. 15 is a circuit configuration diagram of an amplifier circuit according to a second modification of the second embodiment;

FIG. 16 is a graph comparing the efficiency characteristics of the amplifier circuits of the second embodiment, an amplifier circuit of a known example, and the amplifier circuit of the comparative example; and

FIG. 17 provides plan and sectional views of a radio-frequency circuit according to the first modification of the second embodiment.

### DESCRIPTION OF THE EMBODIMENTS

Hereinafter, embodiments of the present disclosure will be described in detail. It should be noted that the embodiments described below provide comprehensive or specific examples. Specifics including numerical values, shapes, materials, constituent elements, arrangements of the constituent elements, and modes of connection given in the following embodiments are merely examples and are not intended to limit the present disclosure. Among the constituent elements in the following embodiments and modifications, constituent elements not recited in any of the independent claims are described as arbitrary constituent elements. The size or size ratio of the constituent elements illustrated in the drawings is not necessarily presented in an exact manner. Like reference symbols denote substantially like configuration elements in the drawings, and redundant descriptions thereof can be omitted or simplified.

In the present disclosure, words used to express relationships between elements, such as parallel and vertical, words used to express the shape of an element, such as rectangular, and numerical ranges do not necessarily denote the exact meanings but denote substantially the same meanings involving, for example, several percent differences.

In the present disclosure, the term “coupled” corresponds to a circuit element being directly coupled to another circuit element by using a connection terminal and/or a wire line conductor and also that a circuit element is electrically coupled to another circuit element via still another circuit element. The expression “coupled between A and B” and the expression “coupled between A and B” corresponds to a circuit element that is coupled to A and B in a path connecting A and B.

In the present disclosure, the plan view of a substrate corresponds to the substrate and circuit elements mounted on the substrate being viewed in the state in which the substrate and circuit elements are orthogonally projected on a plane parallel to the major surface of the substrate.

In the component arrangements of the present disclosure, the expression “a component is disposed at a substrate” includes the case in which the component is disposed at a major surface of the substrate and the case in which the component is disposed within the substrate. The expression “a component is disposed at a major surface of a substrate” includes the case in which the component is disposed in contact with the major surface of the substrate. The expression also includes the case in which the component is disposed above the major surface side without making contact with the major surface (for example, based on the component being stacked on another component that is disposed in contact with the major surface). The expression “a component is disposed at a major surface of a substrate” may include the case in which the component is disposed in a depressed portion formed at the major surface. The expression “a component is disposed within a substrate” includes the case in which the component is encapsulated in the module substrate. The expression also includes the case in which the component is entirely positioned between the two major surfaces of the substrate but not fully covered by the substrate. The expression further includes the case in which a portion of the component is disposed within the substrate.

In the present disclosure, the term “path” refers to a transmission line formed by, for example, a wire line for transferring radio-frequency signals, an electrode directly coupled to the wire line, and a terminal directly coupled to the wire line or electrode.

In the present disclosure, the expression “a component A is provided in series in a path B” corresponds to both of the signal input and signal output ends of the component A being coupled to a wire line, an electrode, or a terminal that constitute the path B.

### First Embodiment

### 1.1 Circuit Configuration of Amplifier Circuit, Radio-Frequency Circuit, and Communication Device

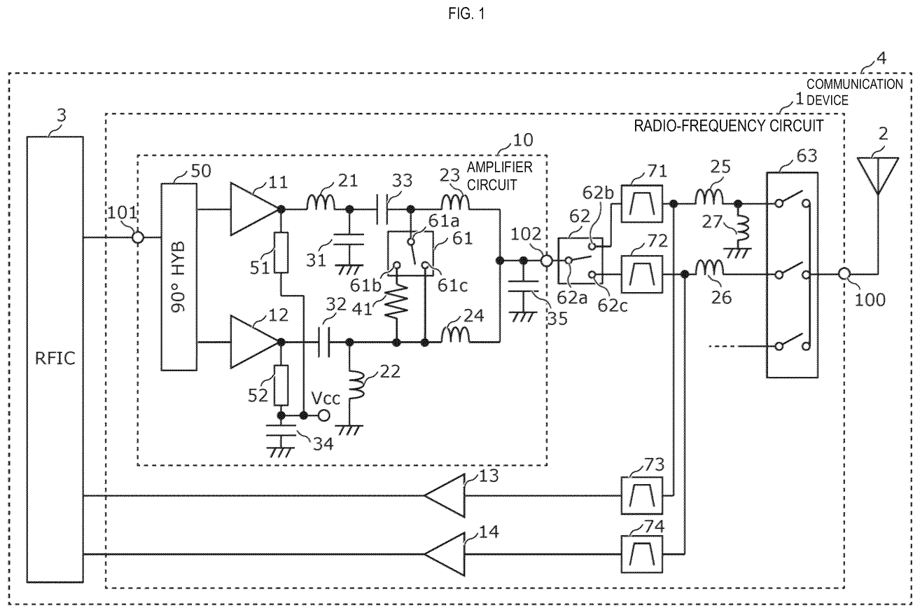

A circuit configuration of an amplifier circuit 10, a radio-frequency circuit 1, and a communication device 4 according to the first embodiment will be described with reference to FIG. 1. FIG. 1 is a circuit configuration diagram of the amplifier circuit 10, the radio-frequency circuit 1, and the communication device 4 according to a first embodiment.

### 1.1.1 Circuit Configuration of Communication Device 4

Firstly, a circuit configuration of the communication device 4 will be described. As illustrated in FIG. 1, the communication device 4 according to the first embodiment includes the radio-frequency circuit 1, an antenna 2, and a radio-frequency (RF) signal processing circuit (RFIC) 3.

The radio-frequency circuit 1 is operable to transfer radio-frequency signals between the antenna 2 and the RFIC 3. A detailed circuit configuration of the radio-frequency circuit 1 will be described later.

The antenna 2 is coupled to an antenna connection terminal 100 of the radio-frequency circuit 1. The antenna 2 is operable to transmit radio-frequency signals outputted from the radio-frequency circuit 1. The antenna 2 may be operable to receive radio-frequency signals from outside and output the radio-frequency signals to the radio-frequency circuit 1.

The RFIC 3 is an example of a signal processing circuit for processing a radio-frequency signal. Specifically, the RFIC 3 is operable to process, for example by up-conversion, a transmit signal inputted from a baseband signal processing circuit (BBIC; not illustrated in the drawing) and output the transmit signal generated by the signal processing to a transmit path in the radio-frequency circuit 1. The RFIC 3 is also operable to process, for example by down-conversion, a receive signal inputted through a receive path in the radio-frequency circuit 1 and output the receive signal generated by the signal processing to the BBIC. The RFIC 3 includes a control unit for controlling the radio-frequency circuit 1. The function of the control unit of the RFIC 3 may be partially or entirely implemented outside the RFIC 3; for example, the function of the control unit of the RFIC 3 may be implemented in the BBIC or the radio-frequency circuit 1.

The RFIC 3 also functions as a control unit for controlling a supply voltage Vcc and a bias current to be supplied to amplifiers included in the amplifier circuit 10. Specifically, the RFIC 3 outputs control signals to a power supply circuit (not illustrated in the drawing) and a bias circuit (not illustrated in the drawing). The power supply circuit and the bias circuit may be provided in the radio-frequency circuit 1 or the amplifier circuit 10. The power supply circuit is operable to supply to the amplifiers of the amplifier circuit 10 the supply voltage Vcc that is controlled based on the control signal. The bias circuit is operable to supply to the amplifiers of the amplifier circuit 10 the bias current that is controlled based on the control signal.

The RFIC 3 also functions as a control unit for controlling connections of switches 61, 62, and 63 included in the radio-frequency circuit 1, based on the communication band (the frequency band) that is in use.

In the communication device 4 according to the first embodiment, the antenna 2 may be omitted.

### 1.1.2 Circuit Configuration of Radio-Frequency Circuit 1

Next, a circuit configuration of the radio-frequency circuit 1 will be described. As illustrated in FIG. 1, the radio-frequency circuit 1 includes the amplifier circuit 10, filters 71, 72, 73, and 74, the switches 62 and 63, low-noise amplifiers 13 and 14, inductors 25, 26, and 27, and the antenna connection terminal 100.

The amplifier circuit 10 is a circuit for amplifying radio-frequency transmit signals (hereinafter referred to as transmit signals) in bands A and B, inputted from a radio-frequency input terminal 101. Instead of the amplifier circuit 10, the radio-frequency circuit 1 may include a first amplifier circuit for amplifying transmit signals in the band A and a second amplifier circuit for amplifying transmit signals in the band B.

In the first embodiment, the bands A and B represent frequency bands determined by, for example, standards organizations such as the 3rd Generation Partnership Project (3GPP, a registered trademark) and the Institute of Electrical and Electronics Engineers (IEEE)) for communication systems built using a radio access technology (RAT). As the communication system in the first embodiment, for example, a 4th Generation Long Term Evolution (4G LTE) system, 5th Generation New Radio (5G NR) system, and Wireless Local Area Network (WLAN) system may be used, but these are not to be interpreted as limiting.

The filter 71 is an example of a first filter. The filter 71 is coupled between the switches 62 and 63. The filter 71 is operable to pass transmit signals in a transmit band of the band A (a first band) among the transmit signals amplified by the amplifier circuit 10. The filter 72 is an example of a second filter. The filter 72 is coupled between the switches 62 and 63. The filter 72 is operable to pass transmit signals in a transmit band of the band B (a second band) among the transmit signals amplified by the amplifier circuit 10.

The filter 73 is coupled between the low-noise amplifier 13 and the switch 63. The filter 73 is operable to pass signals in a receive band of the band A among the receive signals received by the antenna 2. The filter 74 is coupled between the low-noise amplifier 14 and the switch 63. The filter 74 is operable to pass signals in a receive band of the band B among the receive signals received by the antenna 2.

The filters 71 and 73 may form a duplexer for transmitting and receiving signals in the band A or may be implemented by one filter for signal transfer by time division duplexing (TDD). The filters 72 and 74 may form a duplexer for transmitting and receiving signals in the band B or may be implemented by one filter for signal transfer by TDD. Based on the filters 71 and 73 being implemented by one TDD filter, a switch for switching transmission and reception is provided in the stage at least before or after the one filter. Based on the filters 72 and 74 being implemented by one TDD filter, a switch for switching transmission and reception is provided in the stage at least before or after the one filter.

The low-noise amplifier 13 is coupled between the filter 73 and the RFIC 3. The low-noise amplifier 13 is operable to amplify receive signals in the band A and output the receive signals to the RFIC 3. The low-noise amplifier 14 is coupled between the filter 74 and the RFIC 3. The low-noise amplifier 14 is operable to amplify receive signals in the band B and output the receive signals to the RFIC 3.

The switch 62 is an example of a second switch. The switch 62 has a common terminal 62a and selection terminals 62b and 62c. The common terminal 62a is coupled to a radio-frequency output terminal 102 of the amplifier circuit 10. The selection terminal 62b is coupled to the filter 71. The selection terminal 62c is coupled to the filter 72. With this connection configuration, the switch 62 is operable to selectively couple the radio-frequency output terminal 102 to the filter 71 or the filter 72.

The switch 63 is an example of an antenna switch. The switch 63 is coupled to the antenna connection terminal 100. The switch 63 is operable to control connection and disconnection between the antenna connection terminal 100 and the filters 71 and 73 and also control connection and disconnection between the antenna connection terminal 100 and the filters 72 and 74.

The inductor 25 is provided in series in a path connecting the switch 63 and the filters 71 and 73. The inductor 27 is coupled between the path and the ground. The inductors 25 and 27 are operable to provide impedance matching between the switch 63 and the filters 71 and 73. The inductor 26 is provided in series in a path connecting the switch 63 and the filters 72 and 74. The inductor 26 is operable to provide impedance matching between the switch 63 and the filters 72 and 74. At least one of the inductors 25, 26, and 27 may be removed.

The radio-frequency circuit 1 does not necessarily include a receive circuit for transferring receive signals received from the antenna 2 to the RFIC 3. In this case, it may be possible that the radio-frequency circuit 1 does not include the low-noise amplifiers 13 and 14 and the filters 73 and 74.

The circuit configuration described above enables the radio-frequency circuit 1 to transmit and/or receive radio-frequency signals in either the band A or B. The circuit configuration described above also enables the radio-frequency circuit 1 to perform at least one selected from simultaneous transmission, simultaneous reception, and simultaneous transmission and reception with radio-frequency signals in the bands A and B.

For the radio-frequency circuit 1 according to the present disclosure, it is sufficient to include at least the amplifier circuit 10, the switch 62, and the filters 71 and 72 among the configuration elements illustrated in the FIG. 1.

### 1.1.3 Circuit Configuration of Amplifier Circuit 10

Next, a circuit configuration of the amplifier circuit 10 will be described in detail.

As illustrated in FIG. 1, the amplifier circuit 10 includes amplifiers 11 and 12, a 90° hybrid 50, inductors 21, 22, 23, and 24, capacitors 31, 32, 33, 34, and 35, a resistor 41, phase shift lines 51 and 52, the switch 61, the radio-frequency input terminal 101, and the radio-frequency output terminal 102.

The radio-frequency input terminal 101 is coupled to the RFIC 3. The radio-frequency output terminal 102 is an example of an output terminal. The radio-frequency output terminal 102 is coupleable to the antenna connection terminal 100 via the switches 62 and 63 and the filters 71 and 72. Each of the radio-frequency input terminal 101, the radio-frequency output terminal 102, and the antenna connection terminal 100 may be a metal conductor such as a metal electrode or metal bump or may be a point (a node) in a metal wire line.

The amplifier 11 is an example of a first amplifier. The amplifier 11 is a power amplifier for amplifying a radio-frequency signal outputted from one output end of the 90° hybrid 50 and output a first radio-frequency signal (hereinafter referred to as the first signal). The amplifier 12 is an example of a second amplifier. The amplifier 12 is a power amplifier for amplifying a radio-frequency signal outputted from another output end of the 90° hybrid 50 and output a second radio-frequency signal (hereinafter referred to as the second signal).

Each of the amplifiers 11 and 12 includes an amplifier transistor. The amplifier transistor is, for example, a bipolar transistor, such as a heterojunction bipolar transistor (HBT), or a field-effect transistor, such as a metal-oxide-semiconductor field-effect transistor (MOSFET). Based on the amplifier transistor being a bipolar transistor, the input end of each of the amplifiers 11 and 12 is, for example, the base terminal of the bipolar transistor, and the output end of each of the amplifiers 11 and 12 is, for example, the collector terminal of the bipolar transistor. Based on the amplifier transistor being a field-effect transistor, the input end of each of the amplifiers 11 and 12 is, for example, the gate terminal of the field-effect transistor, and the output end of each of the amplifiers 11 and 12 is, for example, the drain terminal of the field-effect transistor.

The input end of the 90° hybrid 50 is coupled to the radio-frequency input terminal 101. The one output end of the 90° hybrid 50 is coupled to the input end of the amplifier 11, and the other output end of the 90° hybrid 50 is coupled to the input end of the amplifier 12. The 90° hybrid 50 is configured to introduces a phase shift of approximately 90° to a radio-frequency signal traveling from the input end to the other output end of the 90° hybrid 50 as compared to a radio-frequency signal traveling from the input end to the one output end of the 90° hybrid 50.

The 90° hybrid 50 may be replaced with a phase shifter circuit having a different circuit configuration.

The inductor 23 is an example of a first phase shifter circuit. The inductor 23 is coupled between the output end of the amplifier 11 and the radio-frequency output terminal 102. The phase difference of radio-frequency signals between two ends of the inductor 23 is, for example, 90°. The inductor 24 is an example of a second phase shifter circuit. The inductor 24 is coupled between the output end of the amplifier 12 and the radio-frequency output terminal 102. The phase difference of radio-frequency signals between two ends of the inductor 24 is, for example, 90°.

The first phase shifter circuit is not necessarily the inductor 23. It is sufficient for the first phase shifter circuit to be a circuit element that introduces a phase shift of 90° to radio-frequency signals. The second phase shifter circuit is not necessarily the inductor 24. It is sufficient for the second phase shifter circuit to be a circuit element that introduces a phase shift of 90° to radio-frequency signals.

The inductor 21 is an example of a first inductor. The inductor 21 is provided in series in a first output path connecting the output end of the amplifier 11 and the inductor 23. The capacitor 31 is an example of a first capacitor. The capacitor 31 is coupled between the first output path and the ground. The inductor 21 and the capacitor 31 form a low pass filter that introduces a phase delay of approximately 450 to radio-frequency signals.

The capacitor 32 is an example of a second capacitor. The capacitor 32 is provided in series in a second output path connecting the output end of the amplifier 12 and the inductor 24. The inductor 22 is an example of a second inductor. The inductor 22 is coupled between the second output path and the ground. The capacitor 32 and the inductor 22 form a high pass filter that introduces a phase advance of approximately 45° to radio-frequency signals.

The amplifier circuit 10 may include, instead of the low pass filter formed by the inductor 21 and the capacitor 31, the third phase shifter circuit that introduces a phase shift of a first phase amount to the first signal, provided in series in the first output path. The amplifier circuit 10 may also include, instead of the high pass filter formed by the capacitor 32 and the inductor 22, a fourth phase shifter circuit that introduces a phase shift of a second phase amount, which is different from the first phase amount by 90°, to the second signal, provided in series in the second output path.

In the first embodiment, the phase amount value and phase difference value of radio-frequency signals do not represent precise numerical values but encompass a range that can be considered substantially equivalent, such as a range with variations of about 30%.

The switch 61 and the resistor 41 form a first circuit. The resistor 41 is an example of a first resistor. The resistor 41 has a first end and a second end.

The first circuit is coupled between a first path connecting the inductors 21 and 23 and a second path connecting the capacitor 32 and the inductor 24. One end (the first end) of the resistor 41 is coupleable to the first path via the switch 61. The other end (the second end) of the resistor 41 is coupled to the second path.

The switch 61 is an example of a first switch. The switch 61 is a single-pole double-throw (SPDT) switch having a common terminal 61a and selection terminals 61b and 61c. The common terminal 61a is coupled to the first path. The selection terminal 61b is coupled to the first end of the resistor 41. The selection terminal 61c is coupled to the second path. With this connection configuration, the switch 61 is operable to selectively couple the first path and the second path to each other either via the resistor 41 or without using the resistor 41. More specifically, by connecting the common terminal 61a to the selection terminal 61b, the first path and the second path are coupled to each other via the resistor 41; by connecting the common terminal 61a to the selection terminal 61c, the first path and the second path are coupled to each other (short-circuited) without using the resistor 41.

The connection relationship between the switch 61 and the resistor 41 may be reversed. Specifically, the common terminal 61a may be coupled to the second path; the selection terminal 61b may be coupled to the first end of the resistor 41; and the selection terminal 61c may be coupled to the first path.

The switch 61 may be a single-pole single-throw (SPST) switch. In this case, the switch 61 is coupled in parallel to the resistor 41 between the first path and the second path. Also with this connection configuration, the switch 61 is operable to selectively couple the first path and the second path to each other either via the resistor 41 or without using the resistor 41 (short-circuited without using the resistor 41). More specifically, by disconnecting the two terminals of the switch 61, the first path and the second path are coupled to each other via the resistor 41; by connecting the two terminals of the switch 61, the first path and the second path are coupled to each other without using the resistor 41 (short-circuited).

The resistor 41 and the inductors 23 and 24 form a Wilkinson power combiner.

The capacitor 33 is provided in series in the first path. The capacitor 33 is operable to inhibit the direct-current supply voltage supplied to the amplifier 11 from leaking toward the radio-frequency output terminal 102. The capacitor 35 is a circuit element for impedance matching, coupled to a path connecting the inductors 23 and 24 and the radio-frequency output terminal 102. The capacitor 35 may be coupled between the path and the ground or provided in series in the path.

The phase shift line 51 is provided in series between the output end of the amplifier 11 and a supply voltage (Vcc) terminal. The phase shift line 51 is operable to inhibit the first signal outputted from the amplifier 11 from leaking into the Vcc terminal. The phase shift line 52 is provided in series between the output end of the amplifier 12 and the supply voltage (Vcc) terminal. The phase shift line 52 is operable to inhibit the second signal outputted from the amplifier 12 from leaking into the Vcc terminal. The capacitor 34 is coupled between the Vcc terminal and the ground. The capacitor 34 is operable to inhibit leakage components of the first signal and the second signal from leaking into the Vcc terminal and also inhibit the supply voltage from flowing to the ground.

In the amplifier circuit 10 according to the first embodiment, the amplifiers 11 and 12, the radio-frequency output terminal 102, the inductors 21, 22, 23, and 24, the capacitors 31 and 32, the resistor 41, and the switch 61 are constituent elements, but the 90° hybrid 50, the capacitors 33, 34, and 35, and the phase shift lines 51 and 52 are not necessarily included.

### 1.1.4 Circuit Configuration of Amplifier Circuit 500 According to First Comparative Example

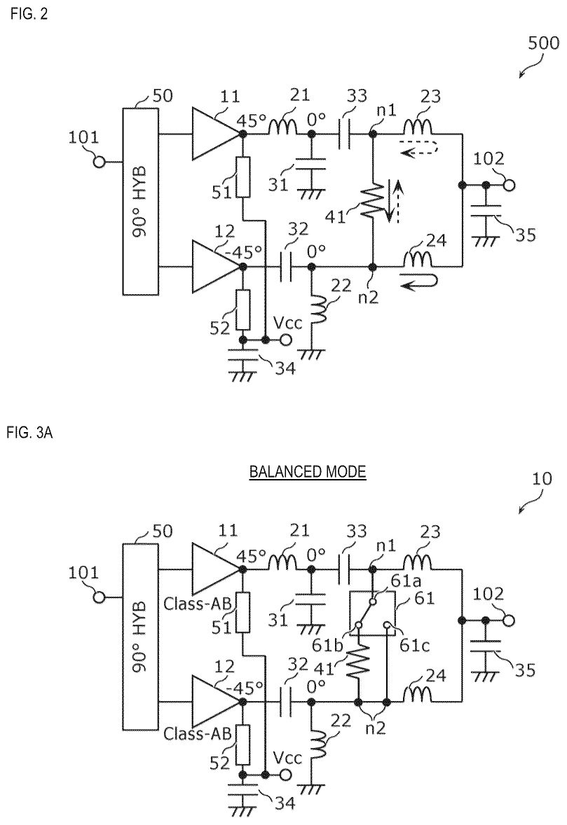

A circuit configuration of an amplifier circuit 500 according to a first comparative example will be described. FIG. 2 is a circuit configuration diagram of the amplifier circuit 500 according to the first comparative example. The amplifier circuit 500 illustrated in the drawing is a known balanced amplifier circuit. The amplifier circuit 500 includes amplifiers 11 and 12, a 90° hybrid 50, inductors 21, 22, 23, and 24, capacitors 31, 32, 33, 34, and 35, a resistor 41, phase shift lines 51 and 52, a radio-frequency input terminal 101, and a radio-frequency output terminal 102. The amplifier circuit 500 according to the first comparative example differs from the amplifier circuit 10 according to the first embodiment in that the switch 61 is not included. In the following, the amplifier circuit 500 according to the first comparative example will be described with a main focus on features that are different from the amplifier circuit 10 according to the first embodiment.

One end of the resistor 41 is coupled to a first path connecting the inductors 21 and 23, and the other end of the resistor 41 is coupled to a second path connecting the capacitor 32 and the inductor 24.

With the configuration described above, the phase difference between a first signal outputted from the amplifier 11 and a second signal outputted from the amplifier 12 is 90°. Specifically, the 90° hybrid 50 causes the phase of the first signal at the output end of the amplifier 11 to shift to +45° and the phase of the second signal at the output end of the amplifier 12 to shift to −45°.

The inductor 21 and the capacitor 31 form a low pass filter. This low pass filter introduces a phase delay of 45° to the first signal, and as a result, the phase of the first signal at the output end of the low pass filter is 0°. The capacitor 32 and the inductor 22 form a high pass filter. This high pass filter introduces a phase advance of 45° to the second signal, and as a result, the phase of the second signal at the output end of the high pass filter is 0°. Overall, the phase of the first signal at a node n1 of the resistor 41 and the first path is aligned with the phase of the second signal at a node n2 of the resistor 41 and the second path.

The phase-aligned first and second signals are transferred through the inductors 23 and 24 and then combined together. The combined radio-frequency signal is outputted from the radio-frequency output terminal 102. At this time, the second signal outputted from the amplifier 12 is reflected by a load coupled to the radio-frequency output terminal 102, and the reflected component of the second signal returns to the node n2. Because the second signal travels through the inductor 24 and returns through the inductor 24, the phase of the reflected component at the node n2 is +180°. By contrast, of the first signal outputted from the amplifier 11, the component traveling from the node n1 toward the resistor 41 has a phase of 0° at the node n2. As a result, the reflected component of the second signal and the first signal, which are in antiphase, cancel each other out in the resistor 41. Similarly, the reflected component of the first signal and the second signal, which are in antiphase, cancel each other out in the resistor 41. This configuration ensures significant isolation between the output end of the amplifier 11 and the output end of the amplifier 12, irrespective of load variations.

However, based on the electric power of the reflected components rising with increases in the output power of radio-frequency signals, a concern arises regarding the electric power handling capability of the resistor 41. Further, there is another concern that the power-added efficiency (PAE) can degrade as the output power of radio-frequency signals increases.

### 1.1.5 Operation Modes of Amplifier Circuit 10

As compared to the amplifier circuit 500 according to the first comparative example, the amplifier circuit 10 according to the first embodiment is able to operate in two modes: a load variation priority mode, which provides tolerance to load variations; and an efficiency priority mode, in which the power-added efficiency (hereinafter referred to as efficiency) is increased.

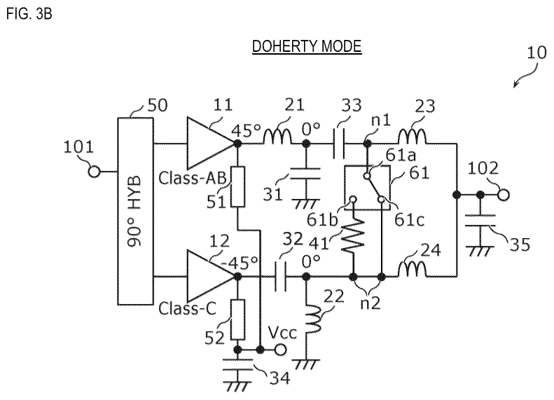

FIG. 3A is a circuit state diagram of the amplifier circuit 10 according to the first embodiment in a first mode. The first mode represents a balanced mode, in other words, the load variation priority mode. As illustrated in the drawing, in the first mode, the common terminal 61a is coupled to the selection terminal 61b, and the common terminal 61a and the selection terminal 61c are disconnected. As a result, the resistor 41 is coupled to the nodes n1 and n2. In this mode, both of the amplifiers 11 and 12 operate in Class AB. Specifically, bias currents that enable operation in Class AB is supplied to the amplifiers 11 and 12.

With this configuration, the phase of the first signal at the output end of the amplifier 11 is +45° and the phase of the second signal at the output end of the amplifier 12 is −45°.

The inductor 21 and the capacitor 31 form a low pass filter. This low pass filter introduces a phase delay of 45° to the first signal, and as a result, the phase of the first signal at the output end of the low pass filter (the node n1) is 0°. The capacitor 32 and the inductor 22 form a high pass filter. This high pass filter introduces a phase advance of 45° to the second signal, and as a result, the phase of the second signal at the output end of the high pass filter (the node n2) is 0°. Thus, the phase of the first signal at the node n1 is aligned with the phase of the second signal at the node n2.

The phase-aligned first and second signals are transferred through the inductors 23 and 24 and then combined together. The combined radio-frequency signal is outputted from the radio-frequency output terminal 102. At this time, the second signal outputted from the amplifier 12 is reflected by a load coupled to the radio-frequency output terminal 102, and the reflected component of the second signal returns to the node n2. Because the second signal travels through the inductor 24 and returns through the inductor 24, the phase of the reflected component at the node n2 is +180°. By contrast, of the first signal outputted from the amplifier 11, the component traveling from the node n1 toward the resistor 41 has a phase of 0° at the node n2. As a result, the reflected component of the second signal and the first signal, which are in antiphase, cancel each other out in the resistor 41. Similarly, the reflected component of the first signal and the second signal, which are in antiphase, cancel each other out in the resistor 41. This configuration ensures significant isolation between the output end of the amplifier 11 and the output end of the amplifier 12, irrespective of load variations. Overall, the first mode achieves enhanced tolerance to load variations.

FIG. 3B is a circuit state diagram of the amplifier circuit 10 according to the first embodiment in a second mode. The second mode represents a Doherty mode, in other words, the efficiency priority mode. As illustrated in the drawing, in the second mode, the common terminal 61a is coupled to the selection terminal 61c, the common terminal 61a and the selection terminal 61b are disconnected, and the nodes n1 and n2 are short-circuited. In this mode, the amplifier 11 operates in Class AB and serves as a carrier amplifier. The amplifier 12 operates in Class C and serves as a peak amplifier. Specifically, the amount of bias current supplied to the amplifier 12 is smaller than the amount of bias current supplied to the amplifier 11.

A carrier amplifier refers to an amplifier element capable of operating in a Doherty amplifier circuit irrespective of whether the input power of radio-frequency signals is high or low, configured to primarily operate in Class AB. A peak amplifier refers to an amplifier element capable of operating in a Doherty amplifier circuit mainly based on the input power of radio-frequency signals being relatively high, configured to primarily operate in Class C. Thus, based on the input power of radio-frequency signals being relatively low, the carrier amplifier mainly amplifies radio-frequency signals; based on the input power of radio-frequency signals being relatively high, both of the carrier amplifier and the peak amplifier amplify radio-frequency signals. With these kinds of operations, in a Doherty amplifier circuit, based on the output power being relatively low, the load impedance observed from the carrier amplifier increases. This configuration thus increases efficiency especially at low output power. Based on the output power being relatively high, both of the carrier amplifier and the peak amplifier operate. This configuration thus reduces the likelihood of signal distortion and improves linearity.

With this configuration, the phase of the first signal at the output end of the amplifier 11 is, for example, +45° and the phase of the second signal at the output end of the amplifier 12 is, for example, −45°.

The inductor 21 and the capacitor 31 form a low pass filter. This low pass filter introduces a phase delay of 450 to the first signal, and as a result, the phase of the first signal at the output end of the low pass filter (the node n1) is 0°. The capacitor 32 and the inductor 22 form a high pass filter. This high pass filter introduces a phase advance of 45° to the second signal, and as a result, the phase of the second signal at the output end of the high pass filter (the node n2) is 0°. Thus, the phase of the first signal at the node n1 is aligned with the phase of the second signal at the node n2.

Based on the input power of radio-frequency signals being relatively low, the amplifier 11 out of the amplifiers 11 and 12 provides amplification, resulting in high-efficiency operation. Based on the input power of radio-frequency signals being relatively high, both of the amplifiers 11 and 12 provide amplification, and the current of the first signal and the current of the second signal are combined at the nodes n1 and n2, resulting in improved linearity. As described above, this configuration enables operations with back-offs that cover the high power output region, in which the amplifiers 11 and 12 are active, to the low power output region, in which the amplifier 11 is active.

Based on the amplifier circuit 10 operating in a low power mode, the first mode may be selected. Based on the amplifier circuit 10 operating in a high power mode, the second mode may be selected.

With this configuration, in the low power mode, the resistor 41 is coupled to the nodes n1 and n2, resulting in the load variation priority mode. In the high power mode, the nodes n1 and n2 are short-circuited, resulting in the efficiency priority mode. As a result, the electric power handling capability of the resistor 41 is eased.

In the low power mode, the maximum output power of the amplifier circuit 10 is relatively small; for example, the maximum output power of the amplifier circuit 10 is smaller than the allowable maximum output power for Power Class 3. In the high power mode, the maximum output power of the amplifier circuit 10 is relatively large; for example, the maximum output power of the amplifier circuit 10 is greater than or equal to the allowable maximum output power for Power Class 3.

Power Classes refer to classification divisions of user equipment (UE) output power, defined by, for example, maximum output power. As the number of power class increases, the allowable output power increases. For example, in 3GPP (registered trademark), the allowable maximum output power for Power Class 1 is 31 dBm, the allowable maximum output power for Power Class 1.5 is 29 dBm, the allowable maximum output power for Power Class 2 is 26 dBm, and the allowable maximum output power for Power Class 3 is 23 dBm.

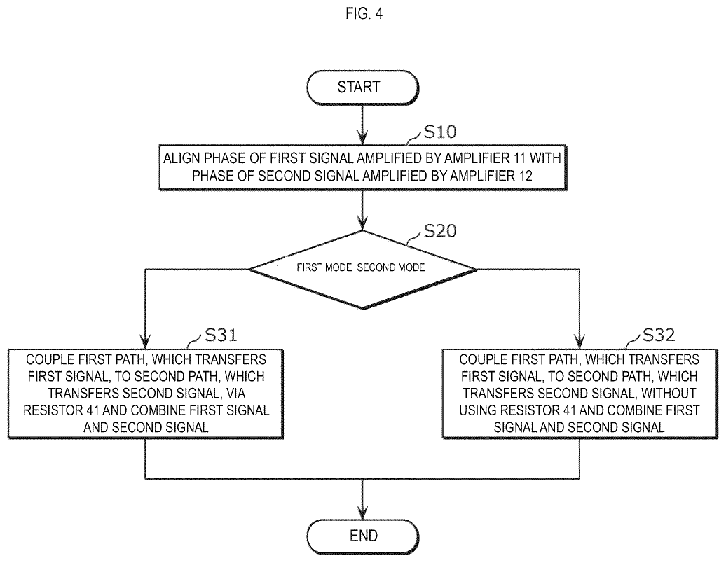

FIG. 4 is a flowchart illustrating an amplification method by the amplifier circuit 10 according to the first embodiment. As illustrated in the drawing, the operation modes of the amplifier circuit 10 include the first mode and the second mode.

The phase difference between radio-frequency signals inputted to the amplifier 11 and radio-frequency signals inputted to the amplifier 12 is approximately 90°.

Firstly, the amplifier circuit 10 aligns the phase of the first signal at the node n1, amplified by the amplifier 11, with the phase of the second signal at the node n2, amplified by the amplifier 12 (S10).

Next, in the first mode (the first mode in S20), the amplifier circuit 10 couples (the node n1 of) the first path, which transfers the phase-aligned first signal, to (the node n2 of) the second path, which transfers the phase-aligned second signal, via the resistor 41 and combines the first signal and the second signal (S31).

By contrast, in the second mode (the second mode in S20), the amplifier circuit 10 couples (the node n1 of) the first path, which transfers the phase-aligned first signal, to (the node n2 of) the second path, which transfers the phase-aligned second signal, without using the resistor 41 and combines the first signal and the second signal (S32).

This method achieves enhanced tolerance to load variations in the first mode and increases efficiency in the second mode.

### 1.1.6 Circuit Configuration of Amplifier Circuit 10A According to First Modification

Next, a circuit configuration of an amplifier circuit 10A according to a first modification will be described.

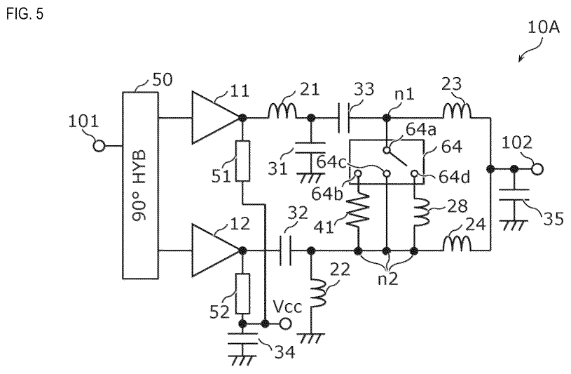

FIG. 5 is a circuit configuration diagram of the amplifier circuit 10A according to the first modification of the first embodiment. As illustrated in the drawing, the amplifier circuit 10A includes amplifiers 11 and 12, a 90° hybrid 50, inductors 21, 22, 23, 24, and 28, capacitors 31, 32, 33, 34, and 35, a resistor 41, phase shift lines 51 and 52, a switch 64, a radio-frequency input terminal 101, and a radio-frequency output terminal 102. The amplifier circuit 10A according to this modification differs from the amplifier circuit 10 according to the first embodiment in the configuration of the first circuit. The following describes the amplifier circuit 10A according to this modification with a main focus on configurational features different from the amplifier circuit 10 according to the first embodiment, and descriptions of the same configurational features as the amplifier circuit 10 according to the first embodiment will not be repeated.

The switch 64, the resistor 41, and the inductor 28 form the first circuit. The resistor 41 is an example of a first resistor. The resistor 41 has the first end and the second end. The inductor 28 is an example of a first circuit element. The inductor 28 may be replaced with a capacitor as the first circuit element.

The first circuit is coupled between the first path connecting the inductors 21 and 23 and the second path connecting the capacitor 32 and the inductor 24. One end (the first end) of the resistor 41 is coupleable to the first path (a node n1) via the switch 64. The other end (the second end) of the resistor 41 is coupled to the second path (a node n2). One end of the inductor 28 is coupleable to the first path (the node n1) via the switch 64. The other end of the inductor 28 is coupled to the second path (a node n2).

The switch 64 is an example of a first switch. The switch 64 is a single-pole 3-throw (SP3T) switch having a common terminal 64a and selection terminals 64b, 64c, and 64d. The common terminal 64a is coupled to the first path (the node n1), the selection terminal 64b is coupled to the first end of the resistor 41, the selection terminal 64c is coupled to the second path (a node n2), and the selection terminal 64d is coupled to the one end of the inductor 28. With this connection configuration, the switch 64 is operable to (1) couple the first path to the second path via the resistor 41, (2) short-circuit the first path and the second path, or (3) couple the first path to the second path via the inductor 28. More specifically, by connecting the common terminal 64a to the selection terminal 64b, the first path and the second path are coupled to each other via the resistor 41; by connecting the common terminal 64a to the selection terminal 64c, the first path and the second path are short-circuited without using the resistor 41; by connecting the common terminal 64a to the selection terminal 64d, the first path and the second path are coupled to each other via the inductor 28.

The connection relationship among the switch 64, the resistor 41, and the inductor 28 may be reversed. Specifically, the common terminal 64a may be coupled to the second path, the selection terminal 64b may be coupled to the first end of the resistor 41, the selection terminal 64d may be coupled to the one end of the inductor 28, and the selection terminal 64c may be coupled to the first path.

The switch 64 may be implemented by two SPST switches. In this case, one of the two SPST switches is coupled in parallel to the resistor 41 between the first path and the second path. The other of the two SPST switches is coupled in parallel to the inductor 28 between the first path and the second path. Also with this connection configuration, the two SPST switches are operable to (1) couple the first path to the second path via the resistor 41, (2) short-circuit the first path and the second path, or (3) couple the first path to the second path via the inductor 28.

The resistor 41 and the inductors 23 and 24 form a Wilkinson power combiner.

In the amplifier circuit 10A according to this modification, the amplifiers 11 and 12, the radio-frequency output terminal 102, the inductors 21, 22, 23, 24, and 28, the capacitors 31 and 32, the resistor 41, and the switch 64 are constituent elements, but the 90° hybrid 50, the capacitors 33, 34, and 35, and the phase shift lines 51 and 52 are not necessarily included.

### 1.1.7 Operation Modes of Amplifier Circuit 10A According to First Modification

As compared to the amplifier circuit 500 according to the first comparative example, the amplifier circuit 10A according to this modification is able to operate in two modes: a load variation priority mode, which provides tolerance to load variations; and an efficiency priority mode, in which efficiency is increased.

In FIG. 5, in a first mode (a balanced mode), the common terminal 64a is coupled to the selection terminal 64b, the common terminal 64a and the selection terminal 64c are disconnected, and the common terminal 64a and the selection terminal 64d are disconnected. As a result, the resistor 41 is coupled to the nodes n1 and n2. In this mode, both of the amplifiers 11 and 12 operate in Class AB. Specifically, bias currents that enable operation in Class AB is supplied to the amplifiers 11 and 12.

With this configuration, the phase of the first signal at the output end of the amplifier 11 is +45° and the phase of the second signal at the output end of the amplifier 12 is −45°. The inductor 21 and the capacitor 31 form a low pass filter. As a result, the phase of the first signal at the output end of the low pass filter (the node n1) is 0°. The capacitor 32 and the inductor 22 form a high pass filter. As a result, the phase of the second signal at the output end of the high pass filter (the node n2) is 0°. Thus, the phase of the first signal at the node n1 is aligned with the phase of the second signal at the node n2.

The first and second signals, the phase of the first signal and the phase of the second signal are aligned at the nodes n1 and n2, are transferred through the inductors 23 and 24 and then combined together. The combined radio-frequency signal is outputted from the radio-frequency output terminal 102. At this time, the second signal is reflected by a load coupled to the radio-frequency output terminal 102, and the reflected component of the second signal returns to the node n2. Because the second signal travels through the inductor 24 and returns through the inductor 24, the phase of the reflected component of the second signal at the node n2 is +180°. By contrast, of the first signal outputted from the amplifier 11, the component traveling from the node n1 toward the resistor 41 has a phase of 0° at the node n2. As a result, the reflected component of the second signal and the first signal, which are in antiphase, cancel each other out in the resistor 41. Similarly, the reflected component of the first signal and the second signal, which are in antiphase, cancel each other out in the resistor 41. This configuration ensures significant isolation between the output end of the amplifier 11 and the output end of the amplifier 12, irrespective of load variations. Overall, the first mode achieves enhanced tolerance to load variations.

In FIG. 5, in a second mode (a Doherty mode), the common terminal 64a is coupled to the selection terminal 64c, the common terminal 64a and the selection terminal 64b are disconnected, and the common terminal 64a and the selection terminal 64d are disconnected. As a result, the nodes n1 and n2 are short-circuited. In this mode, the amplifier 11 operates in Class AB and serves as a carrier amplifier. The amplifier 12 operates in Class C and serves as a peak amplifier. Specifically, the amount of bias current supplied to the amplifier 12 is smaller than the amount of bias current supplied to the amplifier 11.

With this configuration, the phase of the first signal at the output end of the amplifier 11 is +45° and the phase of the second signal at the output end of the amplifier 12 is −45°. The inductor 21 and the capacitor 31 form a low pass filter. As a result, the phase of the first signal at the output end of the low pass filter (the node n1) is 0°. The capacitor 32 and the inductor 22 form a high pass filter. As a result, the phase of the second signal at the output end of the high pass filter (the node n2) is 0°. Thus, the phase of the first signal at the node n1 is aligned with the phase of the second signal at the node n2.

Based on the input power of radio-frequency signals being relatively low, the amplifier 11 out of the amplifiers 11 and 12 provides amplification, resulting in high-efficiency operation. Based on the input power of radio-frequency signals being relatively high, both of the amplifiers 11 and 12 provide amplification, and the current of the first signal and the current of the second signal are combined at the nodes n1 and n2, resulting in improved linearity. As described above, this configuration enables operations with back-offs that cover the high power output region, in which the amplifiers 11 and 12 are active, to the low power output region, in which the amplifier 11 is active.

In FIG. 5, in a third mode (a Doherty mode), the common terminal 64a is coupled to the selection terminal 64d, the common terminal 64a and the selection terminal 64b are disconnected, and the common terminal 64a and the selection terminal 64c are disconnected. As a result, the nodes n1 and n2 are coupled to each other via the inductor 28. In this mode, the amplifier 11 operates in Class AB and serves as a carrier amplifier. The amplifier 12 operates in Class C and serves as a peak amplifier. Specifically, the amount of bias current supplied to the amplifier 12 is smaller than the amount of bias current supplied to the amplifier 11.

With this configuration, the phase of the first signal at the output end of the amplifier 11 is +45° and the phase of the second signal at the output end of the amplifier 12 is −45°. The inductor 21 and the capacitor 31 form a low pass filter. As a result, the phase of the first signal at the output end of the low pass filter (the node n1) is 0°. The capacitor 32 and the inductor 22 form a high pass filter. As a result, the phase of the second signal at the output end of the high pass filter (the node n2) is 0°. Thus, the phase of the first signal at the node n1 is aligned with the phase of the second signal at the node n2.

Based on the input power of radio-frequency signals being relatively low, the amplifier 11 out of the amplifiers 11 and 12 provides amplification, resulting in high-efficiency operation. Based on the input power of radio-frequency signals being relatively high, both of the amplifiers 11 and 12 provide amplification, and the current of the first signal and the current of the second signal are combined at the nodes n1 and n2, resulting in improved linearity. As described above, this configuration enables operations with back-offs that cover the high power output region, in which the amplifiers 11 and 12 are active, to the low power output region, in which the amplifier 11 is active.

In FIG. 5, based on the low power mode being applied to the amplifier circuit 10A, the common terminal 64a is coupled to the selection terminal 64b, the common terminal 64a and the selection terminal 64c are disconnected, and the common terminal 64a and the selection terminal 64d are disconnected. As a result, the resistor 41 is coupled to the nodes n1 and n2. Alternatively, the common terminal 64a is coupled to the selection terminal 64d, the common terminal 64a and the selection terminal 64b are disconnected, and the common terminal 64a and the selection terminal 64c are disconnected. As a result, the inductor 28 is coupled to the nodes n1 and n2. In this mode, the amplifier 11 operates in Class AB. The amplifier 12 does not provide amplification. Specifically, a bias current that enables operation in Class AB is supplied to the amplifier 11, whereas no bias current is supplied to the amplifier 12.

With this configuration, the amplifier 11 provides amplification in the low power mode, resulting in enhanced tolerance to load variations. That is, the amplifier 11 out of the amplifiers 11 and 12 provides amplification, resulting in high-efficiency operation.

In the low power mode, the first mode (the balanced mode) may be used. In this case, the common terminal 64a is coupled to the selection terminal 64b, the common terminal 64a and the selection terminal 64c are disconnected, and the common terminal 64a and the selection terminal 64d are disconnected. As a result, the resistor 41 is coupled to the nodes n1 and n2. In this mode, both of the amplifiers 11 and 12 operate in Class AB. Specifically, bias currents that enable operation in Class AB is supplied to the amplifiers 11 and 12.

This configuration achieves enhanced tolerance to load variations in the low power mode.

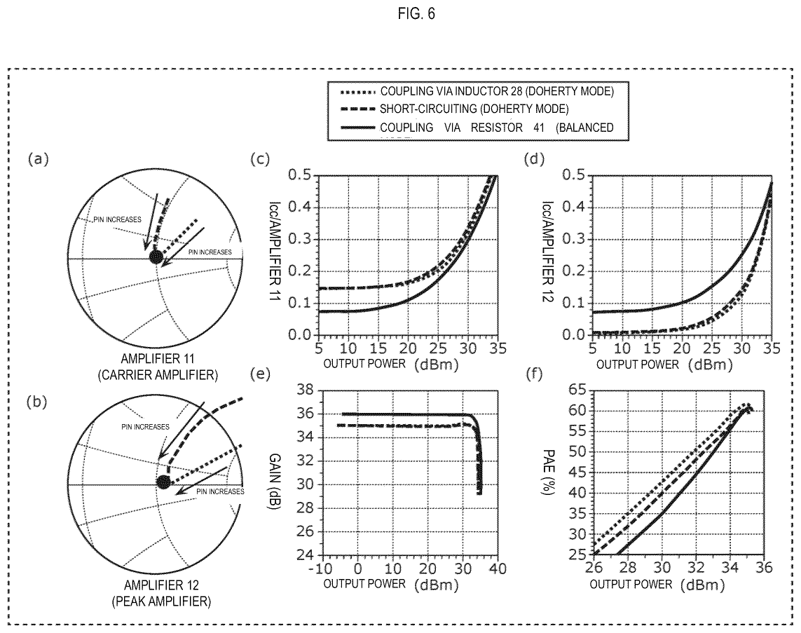

FIG. 6 illustrates load impedance, supply current, gain, and power-added efficiency in the first (balanced) mode, the second (Doherty) mode, and the third (Doherty) mode of the amplifier circuit 10A according to the first modification. In the drawing, (a) illustrates load impedance of the amplifier 11, (b) illustrates load impedance of the amplifier 12, (c) illustrates supply current to the amplifier 11, (d) illustrates supply current to the amplifier 12, (e) illustrates gain of the amplifier circuit 10A, and (f) illustrates power-added efficiency (PAE) of the amplifier circuit 10A.

As illustrated in (a) and (b) of FIG. 6, in the first (balanced) mode, as the input power increases, the load impedance hardly changes. Thus, the amplifier circuit 10A exhibits high tolerance to load variations in the first (balanced) mode.

As illustrated in (f) of FIG. 6, the second (Doherty) mode and the third (Doherty) mode achieve higher efficiency throughout the output power range as compared to the first mode. The third mode achieves higher efficiency than the second mode.

Given these characteristics, based on the amplifier circuit 10A operating in Power Class 1.5, the third mode may be used; based on the amplifier circuit 10A operating in Power Class 2, the second mode may be used; based on the amplifier circuit 10A operating in Power Class 3, the first mode may be used.

With this configuration, based on the amplifier circuit 10A outputting high levels of power, the priority is given to efficiency; based on the amplifier circuit 10A outputting low levels of power, the priority is given to tolerance to load variations.

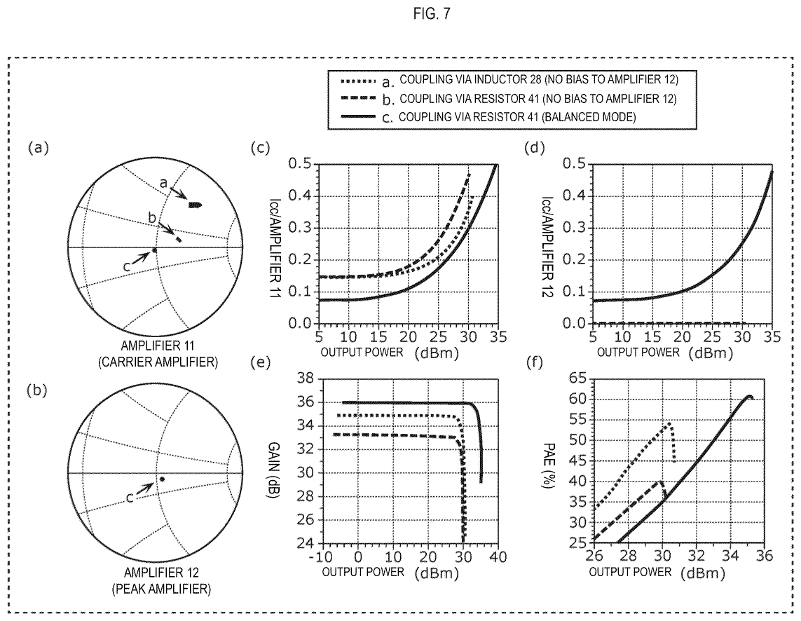

FIG. 7 illustrates load impedance, supply current, gain, and power-added efficiency in the low power mode of the amplifier circuit 10A according to the first modification. The drawing illustrates the characteristics in the following modes: (1) the balanced mode in which the nodes n1 and n2 are coupled to each other via the resistor 41; (2) a mode (a fourth mode) in which the nodes n1 and n2 are coupled to each other via the resistor 41, and the amplifier 11 provides amplification; and (3) a mode (a fifth mode) in which the nodes n1 and n2 are coupled to each other via the inductor 28, and the amplifier 11 provides amplification. In the drawing, (a) illustrates load impedance of the amplifier 11, (b) illustrates load impedance of the amplifier 12, (c) illustrates supply current to the amplifier 11, (d) illustrates supply current to the amplifier 12, (e) illustrates gain of the amplifier circuit 10A, and (f) illustrates power-added efficiency (PAE) of the amplifier circuit 10A.

As illustrated in (a) and (b) of FIG. 7, in the first (balanced) mode, the fourth mode, and the fifth mode, as the input power increases, the load impedance hardly changes. Thus, in the low power mode, the first mode, the fourth mode, and the fifth mode exhibit high tolerance to load variations.

As illustrated in (f) of FIG. 7, the fourth mode and the fifth mode achieve higher efficiency across the low power output region as compared to the first mode. The fifth mode achieves higher efficiency than the fourth mode.

Given these characteristics, based on the amplifier circuit 10A operating in the low power mode, the fourth mode or the fifth mode may be used.

This configuration achieves both enhanced tolerance to load variations and high efficiency based on the amplifier circuit 10A outputting low levels of power.

### 1.1.8 Circuit Configuration of Amplifier Circuit 10B According to Second Modification

Next, a circuit configuration of an amplifier circuit 10B according to a second modification will be described.

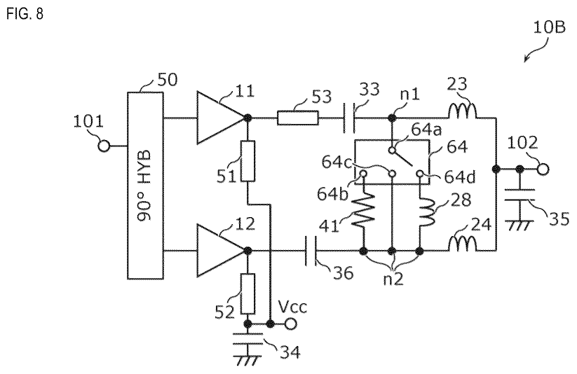

FIG. 8 is a circuit configuration diagram of the amplifier circuit 10B according to the second modification of the first embodiment. As illustrated in the drawing, the amplifier circuit 10B includes amplifiers 11 and 12, a 90° hybrid 50, a λ/4 transmission line 53, inductors 23, 24, and 28, capacitors 33, 34, 35, and 36, a resistor 41, phase shift lines 51 and 52, a switch 64, a radio-frequency input terminal 101, and a radio-frequency output terminal 102. The amplifier circuit 10B according to this modification differs from the amplifier circuit 10A according to the first modification in the configuration of the low pass filter and the configuration of the high pass filter. The following describes the amplifier circuit 10B according to this modification with a main focus on configurational features different from the amplifier circuit 10A according to the first modification, and descriptions of the same configurational features as the amplifier circuit 10A according to the first modification will not be repeated.

The λ/4 transmission line 53 is an example of a third phase shifter circuit. The λ/4 transmission line 53 is provided in series in a first output path connecting the output end of the amplifier 11 and the inductor 23. The λ/4 transmission line 53 introduces a phase shift of the first phase amount to the first signal. In this case, the first phase amount is 90°.

A second output path connecting the output end of the amplifier 12 and the inductor 24 is formed by a wire line, excluding a direct-current (DC) blocking capacitor. The wire line is an example of a fourth phase shifter circuit. The wire line is operable to introduce a phase shift of the second phase amount to the second signal. In this case, the second phase amount is 0°.

The capacitor 36 is provided in series in the second output path. The capacitor 36 is operable to inhibit the direct-current supply voltage supplied to the amplifier 12 from leaking toward the radio-frequency output terminal 102.

In the amplifier circuit 10B according to this modification, the amplifiers 11 and 12, the radio-frequency output terminal 102, the λ/4 transmission line 53, the inductor 23, 24 and 28, the resistor 41, and the switch 64 are constituent elements, but the 90° hybrid 50, the capacitors 33, 34, 35, and 36, and the phase shift lines 51 and 52 are not necessarily included.

This configuration enables selection between the balanced mode and the Doherty mode. As a result, this configuration achieves enhanced tolerance to load variations and also achieves high efficiency.

### 1.2 Component Arrangement of Amplifier Circuit and Radio-Frequency Circuit

Next, a component arrangement of the amplifier circuit 10A and a radio-frequency circuit 1A according to the first modification will be described.

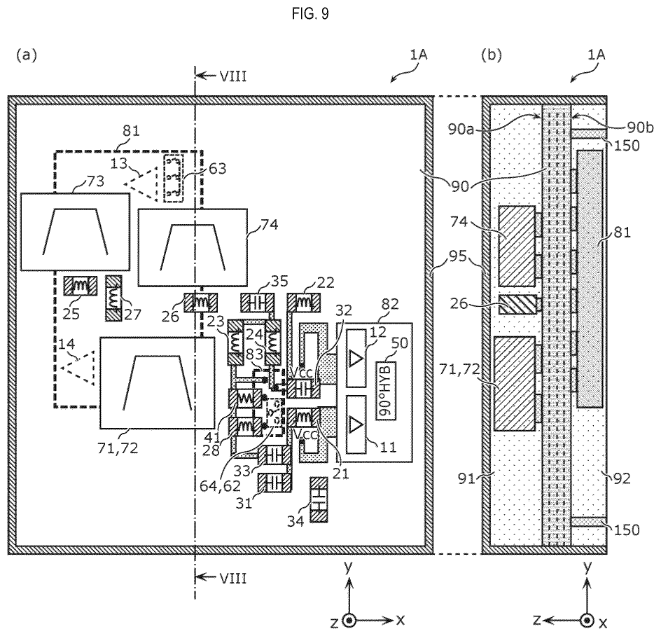

FIG. 9 provides plan and sectional views of the radio-frequency circuit 1A according to the first modification. In FIG. 9, (a) is a cutaway view of an arrangement of circuit components based on a major surface 90a of a module substrate 90 being viewed from the front side in the positive direction of the z axis. In FIG. 9, (b) is a sectional view taken along line VIII-VIII in (a) of FIG. 9. In FIG. 9, some wire lines connecting the module substrate 90 and the circuit components are not illustrated.

In the radio-frequency circuit 1A, the amplifier circuit 10 from the radio-frequency circuit 1 illustrated in FIG. 1 is replaced with the amplifier circuit 10A. The radio-frequency circuit 1A further includes the module substrate 90, resin members 91 and 92, a shield electrode layer 95, and multiple external connection terminals 150.

The module substrate 90 has the major surface 90a and a major surface 90b that are opposite to each other. The circuit components constituting the radio-frequency circuit 1A are mounted on the module substrate 90. For example, a low temperature co-fired ceramic (LTCC) substrate having a layered structure of a plurality of dielectric layers, a high temperature co-fired ceramic (HTCC) substrate, a component-embedded substrate, a substrate including a redistribution layer (RDL), or a printed-circuit board is used as the module substrate 90.

The resin member 91 is disposed over the major surface 90a, covering some of the circuit components and the major surface 90a. The resin member 91 functions to ensure the reliability of the circuit components, including factors such as mechanical strength and moisture resistance. The resin member 92 is disposed over the major surface 90b, covering some of the circuit components and the major surface 90b. The resin member 92 functions to ensure the reliability of the circuit components, including factors such as mechanical strength and moisture resistance.

The shield electrode layer 95 covers the front and side surfaces of the resin member 91 and the side surfaces of the resin member 92. The shield electrode layer 95 is set at a ground potential. This improves the capability to block electromagnetic fields from external circuits.

The resin members 91 and 92 and the shield electrode layer 95 may be omitted for the radio-frequency circuit 1A.

The external connection terminals 150 are disposed at the major surface 90b. The radio-frequency circuit 1A exchanges electrical signals with an external substrate on the front side in the negative direction of the z axis with respect to the radio-frequency circuit 1A, through the external connection terminals 150. Some of the external connection terminals 150 are set at the ground potential of the external substrate.

As illustrated in FIG. 9, the amplifiers 11 and 12, the 90° hybrid 50, the filters 71 to 74, the inductors 21 to 28, the resistor 41, and the capacitors 31 to 35 are disposed at the major surface 90a of the module substrate 90.

The low-noise amplifiers 13 and 14 and the switches 62 to 64 are disposed at the major surface 90b of the module substrate 90.

With this arrangement, the circuit components are disposed separately at the major surface 90a or 90b of the module substrate 90. This arrangement thus reduces the size of the radio-frequency circuit 1A.

The amplifiers 11 and 12 and the 90° hybrid 50 are included in a semiconductor integrated circuit (IC) 82. The low-noise amplifiers 13 and 14 and the switch 63 are included in a semiconductor IC 81. The switches 64 and 62 are included in a semiconductor IC 83.

With this arrangement, the amplifiers 11 and 12 are integrated into one chip, the low-noise amplifiers 13 and 14 and the switch 63 are integrated into one chip, and the switches 64 and 62 are integrated into one chip. This arrangement thus reduces the size of the radio-frequency circuit 1A.

The semiconductor ICs 81, 82, and 83 are made using, for example, complementary metal oxide semiconductor (CMOS). Specifically, the semiconductor ICs 81, 82, and 83 may be manufactured using a silicon on insulator (SOI) process. The semiconductor ICs may be made of at least one of GaAs, SiGe, and GaN. The semiconductor material of the semiconductor ICs 81 to 83 is not limited to the materials presented above.

Based on the module substrate 90 being viewed in plan view, the resistor 41 and the semiconductor IC 83 at least partially overlap.

This arrangement shortens the wire line connecting the resistor 41 and the switch 64, reducing transfer loss of the radio-frequency circuit 1A.

The radio-frequency circuit 1 according to the first embodiment has the same component arrangement as the radio-frequency circuit 1A except that: (1) the switch 61 is replaced with the switch 64, and (2) the inductor 28 is not included.

### 1.3 Effects

As described above, the amplifier circuit 10 according to the first embodiment includes the amplifiers 11 and 12, the radio-frequency output terminal 102, the inductor 23 coupled between the output end of the amplifier 11 and the radio-frequency output terminal 102, the inductor 24 coupled between the output end of the amplifier 12 and the radio-frequency output terminal 102, the inductor 21 provided in series in the first output path connecting the output end of the amplifier 11 and the inductor 23, the capacitor 31 coupled between the first output path and the ground, the capacitor 32 provided in series in the second output path connecting the output end of the amplifier 12 and the inductor 24, the inductor 22 coupled between the second output path and the ground, and the first circuit coupled between the first path connecting the inductors 21 and 23 and the second path connecting the capacitor 32 and the inductor 24. The first circuit includes the resistor 41 having one end coupleable to the first path and the other end coupleable to the second path and the switch 61 configured to selectively couple the first path and the second path to each other either via the resistor 41 or without using the resistor 41.

This configuration achieves enhanced tolerance to load variations in the balanced mode in which the nodes n1 and n2 are coupled to each other via the resistor 41 and also increases efficiency in the Doherty mode in which the nodes n1 and n2 are coupled to each other without using the resistor 41. As such, this configuration achieves both enhanced tolerance to load variations and high efficiency.

In an example, the amplifier circuit 10 according to the first embodiment and the amplifier circuit 10B according to the second modification include the amplifiers 11 and 12, the radio-frequency output terminal 102, the inductor 23 coupled between the output end of the amplifier 11 and the radio-frequency output terminal 102, the inductor 24 coupled between the output end of the amplifier 12 and the radio-frequency output terminal 102, the third phase shifter circuit coupled to the output end of the amplifier 11 and the inductor 23 and configured to introduce a phase shift of the first phase amount to a radio-frequency signal, the fourth phase shifter circuit coupled to the output end of the amplifier 12 and the inductor 24 and configured to introduce a phase shift of the second phase amount, which is different from the first phase amount by 90°, to a radio-frequency signal, and the first circuit coupled between the first path connecting the third phase shifter circuit and the inductor 23 and the second path connecting the fourth phase shifter circuit and the inductor 24. The first circuit includes the resistor 41 having one end coupleable to the first path and the other end coupled to the second path and the switch 61 configured to selectively couple the first path and the second path to each other either via the resistor 41 or without using the resistor 41.

This configuration achieves enhanced tolerance to load variations in the balanced mode in which the nodes n1 and n2 are coupled to each other via the resistor 41 and also increases efficiency in the Doherty mode in which the nodes n1 and n2 are coupled to each other without using the resistor 41. As such, this configuration achieves both enhanced tolerance to load variations and high efficiency.

In an example, in the amplifier circuit 10, the switch 61 has the common terminal 61a and the selection terminals 61b and 61c. The first end of the resistor 41 is coupled to the selection terminal 61b. The common terminal 61a is coupled to one of the first path and the second path. The second end of the resistor 41 is coupled to the other of the first path and the second path. The selection terminal 61c is coupled to the other of the first path and the second path without using any resistor.

With this configuration, the first path and the second path are selectively coupled to each other via the resistor 41 or without using the resistor 41 using the SPDT switch.

In an example, in the amplifier circuit 10, the selection terminal 61c and the other of the first path and the second path are short-circuited.

This configuration enables selective operation in either the balanced mode in which the first path and the second path are coupled to each other via the resistor 41 or the Doherty mode in which the first path and the second path are short-circuited.

In an example, in the amplifier circuit 10, the first path and the second path are short-circuited using the first circuit, the amplifier 11 operates in Class AB, and the amplifier 12 operates in Class C; based on the first path and the second path not being short-circuited using the first circuit, and the resistor 41 is coupled to the first path and the second path, the amplifier 11 operates in Class AB, and the amplifier 12 operates in Class AB.

This configuration enables selective operation in either the balanced mode in which the first path and the second path are coupled to each other via the resistor 41 or the Doherty mode in which the first path and the second path are short-circuited.

In an example, in the amplifier circuit 10, based on the low power mode being applied, the first path and the second path are not short-circuited using the first circuit, and the resistor 41 is coupled to the first path and the second path; based on the high power mode being applied, the first path and the second path are short-circuited using the first circuit.

With this configuration, the balanced mode is used in the low power mode, and the high power mode is used in the Doherty mode. This configuration thus achieves enhanced tolerance to load variations in the low power output region and high efficiency in the high power output region.

In an example, in the amplifier circuit 10A according to the first modification, the first circuit further includes the first circuit element, which is the inductor 28 or a capacitor. The switch 64 has the common terminal 64a and the selection terminals 64b, 64c, and 64d. The first end of the resistor 41 is coupled to the selection terminal 64b. The common terminal 64a is coupled to one of the first path and the second path. The second end of the resistor 41 is coupled to the other of the first path and the second path. The selection terminal 61c is coupled to the other of the first path and the second path. One end of the first circuit element is coupled to the selection terminal 64d. The other end of the first circuit element is coupled to the other of the first path and the second path.

This configuration achieves enhanced tolerance to load variations in the balanced mode in which the nodes n1 and n2 are coupled to each other via the resistor 41 and also increases efficiency in the Doherty mode in which the nodes n1 and n2 are short-circuited or the Doherty mode in which the nodes n1 and n2 are coupled to each other using the first circuit element. As such, this configuration achieves both enhanced tolerance to load variations and high efficiency.

In an example, in the amplifier circuit 10A, based on the first path and the second path being short-circuited, the amplifier 11 operates in Class AB, and the amplifier 12 operates in Class C; based on the first circuit element being coupled to the first path and the second path, the amplifier 11 operates in Class AB, and the amplifier 12 operates in Class C; based on the resistor 41 being coupled to the first path and the second path, the amplifier 11 operates in Class AB, and the amplifier 12 operates in Class AB.

This configuration enables selective operation in the balanced mode in which the first path and the second path are coupled to each other via the resistor 41, the Doherty mode in which the first path and the second path are short-circuited, or the Doherty mode in which the first path and the second path are coupled to each other using the first circuit element.

In an example, based on the amplifier circuit 10A operating in Power Class 1.5, the first circuit element is coupled to the first path and the second path; based on the amplifier circuit 10A operating in Power Class 2, the first path and the second path are short-circuited; based on the amplifier circuit 10A operating in Power Class 3, the resistor 41 is coupled to the first path and the second path.

This configuration achieves enhanced tolerance to load variations in Power Class 3 and achieves high efficiency in Power Classes 1.5 and 2.

In an example, based on the low power mode being applied to the amplifier circuit 10A, the resistor 41 is coupled to the first path and the second path.

This configuration achieves enhanced tolerance to load variations in the low power mode.

In an example, the radio-frequency circuit 1 according to the first embodiment and the radio-frequency circuit 1A according to the first modification includes the amplifier circuit 10 (or the amplifier circuit 10A), the filter 71 having the pass band that includes at least a portion of the band A, the filter 72 having the pass band that includes at least a portion of the band B, and the switch 62 configured to selectively couple the radio-frequency output terminal 102 to the filter 71 or the filter 72.

This configuration enables the radio-frequency circuit 1 (and the radio-frequency circuit 1A) to support multiple bands.

In an example, the radio-frequency circuits 1 and 1A further include the module substrate 90 having the major surfaces 90a and 90b that are opposite to each other and the external connection terminals 150 disposed at the major surface 90b. The amplifiers 11 and 12 are disposed at the major surface 90a. The switch 61 (or 64) and the switch 62 are disposed at the major surface 90b.

With this arrangement, the circuit components are disposed separately at the major surface 90a or 90b of the module substrate 90. This arrangement thus reduces the size of the radio-frequency circuit 1 (and the radio-frequency circuit 1A).

In an example, in the radio-frequency circuits 1 and 1A, the switch 61 (or 64) and the switch 62 are included in one semiconductor IC 83.

With this configuration, the switches 61 (or 64) and 62 are integrated into one chip. This configuration thus reduces the size of the radio-frequency circuit 1 (and the radio-frequency circuit 1A).

In an example, in the radio-frequency circuits 1 and 1A, the resistor 41 is disposed at the major surface 90a. Based on the module substrate 90 being viewed in plan view, the resistor 41 and the semiconductor IC 83 at least partially overlap.

This arrangement shortens the wire line connecting the resistor 41 and the switch 61 (or 64), reducing transfer loss of the radio-frequency circuit 1 (and the radio-frequency circuit 1A).

The communication device 4 according to the first embodiment includes the RFIC 3 configured to process radio-frequency signals and the amplifier circuit 10 configured to transfer radio-frequency signals between the RFIC 3 and the antenna 2.

This configuration enables the communication device 4 to achieve the effects of the amplifier circuit 10.

In the amplification method according to the first embodiment, the phase of the first signal amplified by the amplifier 11 and the phase of the second signal amplified by the amplifier 12 are aligned with each other. In the first mode, the first path, which transfers the phase-aligned first signal, and the second path, which transfers the phase-aligned second signal, are coupled to each other via the resistor 41, and the first signal and the second signal are combined. In the second mode, the first path, which transfers the phase-aligned first signal, and the second path, which transfers the phase-aligned second signal, are coupled to each other without using the resistor 41, and the first signal and the second signal are combined.

With this configuration, the first mode functions as the balanced mode, achieving enhanced tolerance to load variations; the second mode functions as the Doherty mode, increasing efficiency.

### Second Embodiment

In the first embodiment, the amplifier circuit capable of high-efficiency operation in both of the balanced mode and the Doherty mode has been described. By contrast, in the second embodiment, an amplifier circuit capable of high-efficiency operation in the Doherty mode will be described.

### 2.1 Circuit Configuration of Amplifier Circuit, Radio-Frequency Circuit, and Communication Device

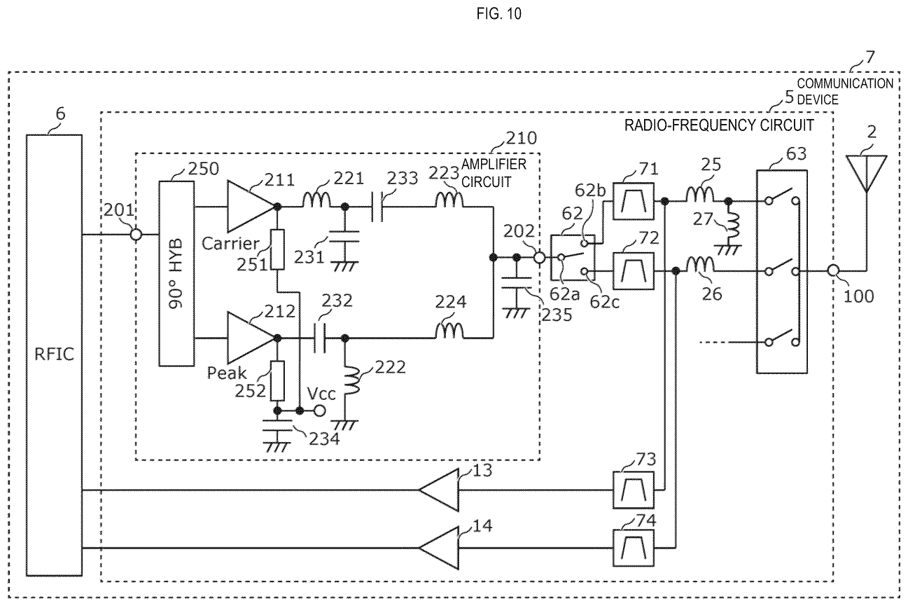

A circuit configuration of an amplifier circuit 210, a radio-frequency circuit 5, and a communication device 7 according to the second embodiment will be described with reference to FIG. 10. FIG. 10 is a circuit configuration diagram of the amplifier circuit 210, the radio-frequency circuit 5, and the communication device 7 according to the second embodiment.

### 2.1.1 Circuit Configuration of Communication Device 7

Firstly, a circuit configuration of the communication device 7 will be described. As illustrated in FIG. 10, the communication device 7 according to the second embodiment includes the radio-frequency circuit 5, an antenna 2, and an RFIC 6. The communication device 7 according to the second embodiment differs from the communication device 4 according to the first embodiment in the configuration of the amplifier circuit 210. The following thus describes the communication device 7 according to the second embodiment with a main focus on the circuit configuration of the amplifier circuit 210, and descriptions of the same configurational features as the communication device 4 according to the first embodiment will not be repeated.

The radio-frequency circuit 5 is operable to transfer radio-frequency signals between the antenna 2 and the RFIC 6.

The antenna 2 is coupled to an antenna connection terminal 100 of the radio-frequency circuit 5. The antenna 2 is operable to transmit radio-frequency signals outputted from the radio-frequency circuit 5. The antenna 2 may be operable to receive radio-frequency signals from outside and output the radio-frequency signals to the radio-frequency circuit 5.

The RFIC 6 is an example of a signal processing circuit for processing a radio-frequency signal. Specifically, the RFIC 6 is operable to process, for example by up-conversion, a transmit signal inputted from a BBIC and output the transmit signal generated by the signal processing to a transmit path in the radio-frequency circuit 5. The RFIC 6 is also operable to process, for example by down-conversion, a receive signal inputted through a receive path in the radio-frequency circuit 5 and output the receive signal generated by the signal processing to the BBIC.

In the communication device 7 according to the second embodiment, the antenna 2 may be omitted.

### 2.1.2 Circuit Configuration of Radio-Frequency Circuit 5

As illustrated in FIG. 10, the radio-frequency circuit 5 includes the amplifier circuit 210, filters 71, 72, 73, and 74, switches 62 and 63, low-noise amplifiers 13 and 14, inductors 25, 26, and 27, and the antenna connection terminal 100.

The amplifier circuit 210 is a circuit for amplifying transmit signals in the bands A and B, inputted from a radio-frequency input terminal 201.

The filters 71 to 74, the switches 62 and 63, the low-noise amplifiers 13 and 14, and the inductors 25 to 27 are the same as the circuit components included in the radio-frequency circuit 1 according to the first embodiment, and descriptions thereof will not be repeated.

The circuit configuration described above enables the radio-frequency circuit 5 to transmit and/or receive radio-frequency signals in either the band A or B. The circuit configuration described above also enables the radio-frequency circuit 5 to perform at least one selected from simultaneous transmission, simultaneous reception, and simultaneous transmission and reception with radio-frequency signals in the bands A and B.

For the radio-frequency circuit 5 according to the present disclosure, it is sufficient to include at least the amplifier circuit 210, the switch 62, and the filters 71 and 72 among the configuration elements illustrated in the FIG. 10.

### 2.1.3 Circuit Configuration of Amplifier Circuit 210

Next, a circuit configuration of the amplifier circuit 210 will be described in detail.

As illustrated in FIG. 10, the amplifier circuit 210 includes a carrier amplifier 211 and a peak amplifier 212, a 90° hybrid 250, inductors 221, 222, 223, and 224, capacitors 231, 232, 233, 234, and 235, phase shift lines 251 and 252, the radio-frequency input terminal 201, and a radio-frequency output terminal 202. The amplifier circuit 210 according to the second embodiment differs from the amplifier circuit 10 according to the first embodiment in that: the switch 61 and the resistor 41 are not included; and the amplifiers 11 and 12 are replaced with the carrier amplifier 211 and the peak amplifier 212, which are specifically designed for the Doherty mode. The following describes the amplifier circuit 210 according to the second embodiment with a main focus on configurational features different from the amplifier circuit 10 according to the first embodiment, and descriptions of the same configurational features as the amplifier circuit 10 according to the first embodiment will not be repeated.

The radio-frequency input terminal 201 is coupled to the RFIC 6. The radio-frequency output terminal 202 is an example of an output terminal. The radio-frequency output terminal 202 is coupleable to the antenna connection terminal 100 via the switches 62 and 63 and the filters 71 and 72.

The carrier amplifier 211 is a Class-A (or Class-AB) amplifier circuit capable of amplification for all power levels of the first radio-frequency signal outputted from one output end of the 90° hybrid 250. The carrier amplifier 211 is capable of highly efficient amplification especially in the low power output region and the middle power output region.

The peak amplifier 212 is a Class-C amplifier circuit capable of amplification for high power levels of the second radio-frequency signal outputted from the other output end of the 90° hybrid 250. An amplifier transistor included in the peak amplifier 212 is configured to receive a bias voltage lower than a bias voltage applied to an amplifier transistor included in the carrier amplifier 211. As a result, as the power level of the second radio-frequency signal increases, the output impedance decreases. With this configuration, the peak amplifier 212 is able to provide low-distortion amplification in the high power output region.

Each of the carrier amplifier 211 and the peak amplifier 212 includes an amplifier transistor. The amplifier transistor is, for example, a bipolar transistor, such as an HBT, or a field-effect transistor, such as a MOSFET.

The input end of the 90° hybrid 250 is coupled to the radio-frequency input terminal 201. The one output end of the 90° hybrid 250 is coupled to the input end of the carrier amplifier 211, and the other output end of the 90° hybrid 250 is coupled to the input end of the peak amplifier 212.

The inductor 223 is an example of a third inductor. The inductor 223 is coupled between the output end of the carrier amplifier 211 and the radio-frequency output terminal 202. The phase difference of radio-frequency signals between two ends of the inductor 223 is, for example, 45°. The inductor 224 is an example of a fourth inductor. The inductor 224 is coupled between the output end of the peak amplifier 212 and the radio-frequency output terminal 202. The phase difference of radio-frequency signals between two ends of the inductor 224 is, for example, 45°.

The circuit component coupled between the output end of the carrier amplifier 211 and the radio-frequency output terminal 202 is not necessarily the inductor 223; the circuit component may be a first phase shifter circuit for introducing a phase shift of 45° to radio-frequency signals. The first phase shifter circuit is, for example, a circuit including the inductor 223 or a ⅛ wavelength transmission line.

The circuit component coupled between the output end of the peak amplifier 212 and the radio-frequency output terminal 202 is not necessarily the inductor 224; the circuit component may be a second phase shifter circuit for introducing a phase shift of 45° to radio-frequency signals. The second phase shifter circuit is, for example, a circuit including the inductor 224 or a ⅛ wavelength transmission line.

It is desirable that: the first phase shifter circuit introduce a phase shift of the first phase amount to the first radio-frequency signal; the second phase shifter circuit introduce a phase shift of the second phase amount to the second radio-frequency signal; the first phase amount be equal to the second phase amount.

This configuration enables low-loss current combining at the radio-frequency output terminal 202, combining the first radio-frequency signal having travelled through the 90° hybrid 250, the carrier amplifier 211, the inductor 221, and the first phase shifter circuit and the second radio-frequency signal having travelled through the 90° hybrid 250, the peak amplifier 212, the capacitor 232, and the second phase shifter circuit.

It is desirable that based on the first phase shifter circuit being the inductor 223 provided in series in a path connecting the inductor 221 and the radio-frequency output terminal 202, and the second phase shifter circuit is the inductor 224 provided in series in a path connecting the capacitor 232 and the radio-frequency output terminal 202, the inductance of the inductor 223 be equal to the inductance of the inductor 224.

This configuration enables low-loss current combining at the radio-frequency output terminal 202, combining the first radio-frequency signal having travelled through the 90° hybrid 250, the carrier amplifier 211, and the inductors 221 and 223 and the second radio-frequency signal having travelled through the 90° hybrid 250, the peak amplifier 212, the capacitor 232, and the inductor 224.

The inductor 221 is an example of a first inductor. The inductor 221 is provided in series in a first output path connecting the output end of the carrier amplifier 211 and the inductor 223. The capacitor 231 is an example of a first capacitor. The capacitor 231 is coupled between the first output path and the ground. The inductor 221 and the capacitor 231 form a low pass filter that introduces a phase delay of approximately 450 to radio-frequency signals.

The capacitor 232 is an example of a second capacitor. The capacitor 232 is provided in series in a second output path connecting the output end of the peak amplifier 212 and the inductor 224. The inductor 222 is an example of a second inductor. The inductor 222 is coupled between the second output path and the ground. The capacitor 232 and the inductor 222 form a high pass filter that introduces a phase advance of approximately 45° to radio-frequency signals.

The amplifier circuit 210 may include, instead of the low pass filter formed by the inductor 221 and the capacitor 231, a fourth phase shifter circuit that introduces a phase shift of a fourth phase amount to the first radio-frequency signal, provided in series in the first output path. The amplifier circuit 210 may also include, instead of the high pass filter formed by the capacitor 232 and the inductor 222, a fifth phase shifter circuit that introduces a phase shift of a fifth phase amount, which is different from the fourth phase amount by 90°, to the second radio-frequency signal, provided in series in the second output path.

In the second embodiment, the phase amount value and phase difference value of radio-frequency signals do not represent precise numerical values but encompass a range that can be considered substantially equivalent, such as a range with variations of about 30%.

In the amplifier circuit 210 according to the second embodiment, no resistor is coupled between the path connecting the inductor 221 and the inductor 223 and the path connecting the capacitor 232 and the inductor 224.

The capacitor 233 is provided in series in the first path. The capacitor 233 is operable to inhibit the direct-current supply voltage supplied to the carrier amplifier 211 from leaking toward the radio-frequency output terminal 202. The capacitor 235 is a circuit element for impedance matching, coupled to a path connecting the inductors 223 and 224 and the radio-frequency output terminal 202. The capacitor 235 may be coupled between the path and the ground or provided in series in the path.

The phase shift line 251 is provided in series between the output end of the carrier amplifier 211 and the supply voltage (Vcc) terminal. The phase shift line 251 is operable to inhibit the first radio-frequency signal outputted from the carrier amplifier 211 from leaking into the Vcc terminal. The phase shift line 252 is provided in series between the output end of the peak amplifier 212 and the supply voltage (Vcc) terminal. The phase shift line 252 is operable to inhibit the second radio-frequency signal outputted from the peak amplifier 212 from leaking into the Vcc terminal. The capacitor 234 is coupled between the Vcc terminal and the ground. The capacitor 234 is operable to inhibit leakage components of the first radio-frequency signal and the second radio-frequency signal from leaking into the Vcc terminal and also inhibit the supply voltage from flowing to the ground.

In the amplifier circuit 210 according to the second embodiment, the carrier amplifier 211, the peak amplifier 212, the radio-frequency output terminal 202, the inductors 221, 222, 223, and 224, and the capacitors 231 and 232 are constituent elements, but the 90° hybrid 250, the capacitors 233, 234, and 235, and the phase shift lines 251 and 252 are not necessarily included.

### 2.1.4 Circuit Configuration of Amplifier Circuit 600 According to Second Comparative Example

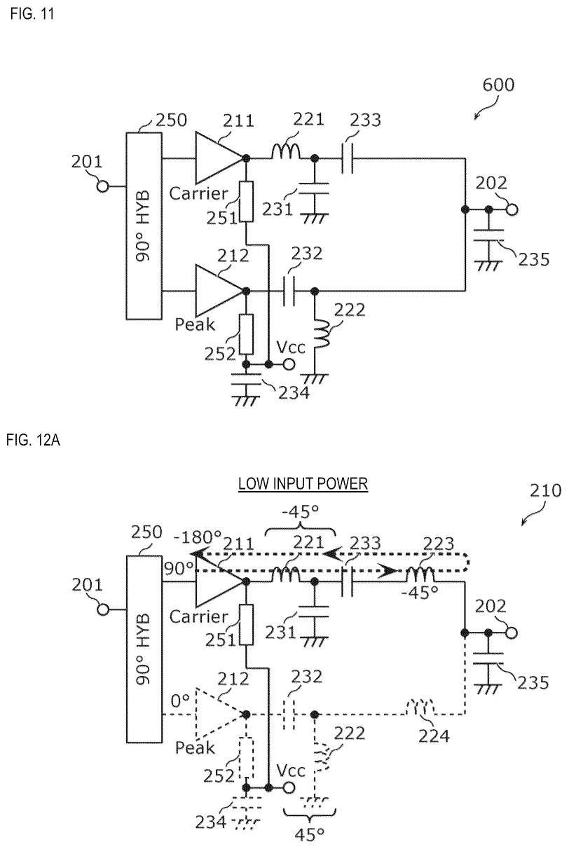

A circuit configuration of an amplifier circuit 600 according to a second comparative example will be described. FIG. 11 is a circuit configuration diagram of the amplifier circuit 600 according to the second comparative example. The amplifier circuit 600 illustrated in the drawing is a known Doherty amplifier circuit (Doherty half amplifier circuit). The amplifier circuit 600 includes a carrier amplifier 211 and a peak amplifier 212, a 90° hybrid 250, inductors 221 and 222, capacitors 231, 232, 233, 234, and 235, phase shift lines 251 and 252, a radio-frequency input terminal 201, and a radio-frequency output terminal 202. The amplifier circuit 600 according to the second comparative example differs from the amplifier circuit 210 according to the second embodiment in that the inductors 223 and 224 are not provided.

With the configuration described above, the 90° hybrid 250 introduces a phase difference of 90° between the first radio-frequency signal outputted from the carrier amplifier 211 and the second radio-frequency signal outputted from the peak amplifier 212. For example, the phase of the first radio-frequency signal outputted from the carrier amplifier 211 is 90°, and the phase of the second radio-frequency signal outputted from the peak amplifier 212 is 0°.

The inductor 221 and the capacitor 231 form a low pass filter. This low pass filter introduces a phase delay of approximately 45° to the first radio-frequency signal, and as a result, the phase of the first radio-frequency signal at the output end of the low pass filter is approximately 45°. The capacitor 232 and the inductor 222 form a high pass filter. This high pass filter introduces a phase advance of approximately 45° to the second radio-frequency signal, and as a result, the phase of the second radio-frequency signal at the output end of the high pass filter is approximately 45°. Overall, the phase of the first radio-frequency signal and the phase of the second radio-frequency signal are aligned with each other at the radio-frequency output terminal 202, so that the current of the first radio-frequency signal and the current of the second radio-frequency signal are combined with low loss.

Based on the power of radio-frequency signals inputted from the radio-frequency input terminal 201 being relatively low (low input power), the peak amplifier 212 is turned off. As a result, the impedance based on the load side (the radio-frequency output terminal 202 side) being observed from the output end of the carrier amplifier 211 (hereinafter referred to as the load impedance of the carrier amplifier 211) is relatively high. As such, this configuration increases efficiency of the amplifier circuit 600 in the input power region.

Next, based on the power of radio-frequency signals inputted from the radio-frequency input terminal 201 being relatively high (high input power), the peak amplifier 212 is turned on. As a result, the load impedance of the carrier amplifier 211 is relatively low. This configuration enables low-distortion amplification in the high input power region, increasing peak power.

Overall, shifting the load impedance of the carrier amplifier 211 constituting the Doherty amplifier circuit 600 increases efficiency (back-off efficiency) in the region in which the peak amplifier 212 changes from the on-state to the off-state and also ensures peak power in the region in which the peak amplifier 212 is in the on-state.

However, in the amplifier circuit 600 according to the second comparative example, based on high input power being changed to low input power, the phase difference between the first radio-frequency signal outputted from the carrier amplifier 211 and the first radio-frequency signal reflected by the load and returned to the output end of the carrier amplifier 211 is the phase difference corresponding to the behavior of a signal traveling through the low pass filter and returning through the low pass filter, that is, approximately 90° (450×2). Thus, based on high input power being changed to low input power, the load impedance of the carrier amplifier 211 shifts in response to a phase shift as small as 90°, instead of a 1800 phase shift (phase inversion). Therefore, the amplifier circuit 600 according to the second comparative example has a problem that the back-off level is as small as about 3 dB, which is based on the change of the peak amplifier 212 from the on-state to the off-state, and this configuration does not sufficiently improve efficiency at low input power.

### 2.1.5 Operation Modes of Amplifier Circuit 210

Because the amplifier circuit 210 according to the second embodiment additionally includes the first phase shifter circuit (the inductor 223) and the second phase shifter circuit (the inductor 224), the amplifier circuit 210 is able to shift the load impedance of the carrier amplifier 211 to a greater extent than the amplifier circuit 600 according to the second comparative example.

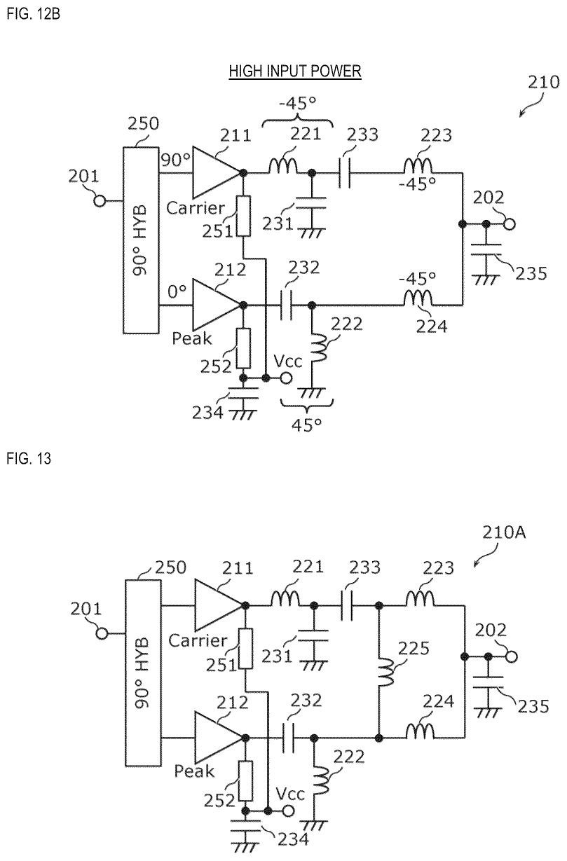

FIG. 12A is a circuit state diagram of the amplifier circuit 210 according to the second embodiment at low input power. FIG. 12B is a circuit state diagram of the amplifier circuit 210 according to the second embodiment at high input power.

In the amplifier circuit 210, the 90° hybrid 250 introduces a phase difference of 90° between the first radio-frequency signal outputted from the carrier amplifier 211 and the second radio-frequency signal outputted from the peak amplifier 212. For example, the phase of the first radio-frequency signal outputted from the carrier amplifier 211 is 90°, and the phase of the second radio-frequency signal outputted from the peak amplifier 212 is 0°.

The low pass filter formed by the inductor 221 and the capacitor 231 delays the phase of the first radio-frequency signal by approximately 45°, and the inductor 223 further delays the phase of the first radio-frequency signal by approximately 45°. Consequently, the phase of the first radio-frequency signal at the radio-frequency output terminal 202 is 0°. The high pass filter formed by the capacitor 232 and the inductor 222 advances the phase of the second radio-frequency signal by approximately 45°, and the inductor 224 delays the phase of the second radio-frequency signal by approximately 45°. Consequently, the phase of the second radio-frequency signal at the radio-frequency output terminal 202 is 0°. Overall, the phase of the first radio-frequency signal and the phase of the second radio-frequency signal are aligned with each other at the radio-frequency output terminal 202, so that the current of the first radio-frequency signal and the current of the second radio-frequency signal are combined with low loss.

As illustrated in FIG. 12A, the peak amplifier 212 is turned off at low input power. As a result, the load impedance of the carrier amplifier 211 is relatively high. As such, this configuration increases efficiency of the amplifier circuit 210 in the input power region.

Next, as illustrated in FIG. 12B, the peak amplifier 212 is turned on at high input power. As a result, the load impedance of the carrier amplifier 211 is relatively low. This configuration enables low-distortion amplification in the high input power region, increasing peak power.

Overall, shifting the load impedance of the carrier amplifier 211 constituting the Doherty amplifier circuit 210 increases efficiency (back-off efficiency) in the region in which the peak amplifier 212 changes from the on-state to the off-state and also ensures peak power in the region in which the peak amplifier 212 is in the on-state.

Based on high input power being changed to low input power, the phase difference between the first radio-frequency signal outputted from the carrier amplifier 211 and the first radio-frequency signal reflected by the load and returned to the output end of the carrier amplifier 211 is the phase difference corresponding to the behavior of a signal traveling through the low pass filter and the inductor 223 and returning through the low pass filter and the inductor 223, that is, approximately 1800 ((45°+45°)×2). Thus, based on high input power being changed to low input power, the load impedance of the carrier amplifier 211 shifts in response to a 1800 phase shift (phase inversion). With this configuration, the amplifier circuit 210 according to the second embodiment achieves a back-off level of 6 dB, which is the total of the back-off level based on the change of the peak amplifier 212 from the on-state to the off-state and the back-off level based on the shift of load impedance by phase inversion. This configuration improves efficiency (efficiency in the back-off region) at low input power.

As a result, with modulation methods using relatively large Peak-to-Average Power Ratios (PAPRs) of about 6 dB, the amplifier circuit 210 according to the second embodiment achieves high efficiency throughout a wider range of input power levels than the amplifier circuit 600 according to the second comparative example.

### 2.1.6 Circuit Configuration of Amplifier Circuit 210A According to First Modification

FIG. 13 is a circuit configuration diagram of an amplifier circuit 210A according to a first modification of the second embodiment. As illustrated in the drawing, the amplifier circuit 210A includes a carrier amplifier 211 and a peak amplifier 212, a 90° hybrid 250, inductors 221, 222, 223, 224, and 225, capacitors 231, 232, 233, 234, and 235, phase shift lines 251 and 252, a radio-frequency input terminal 201, and a radio-frequency output terminal 202. The amplifier circuit 210A according to this modification differs from the amplifier circuit 210 according to the second embodiment in that the inductor 225 is additionally included. The following describes the amplifier circuit 210A according to this modification with a main focus on configurational features different from the amplifier circuit 210 according to the second embodiment, and descriptions of the same configurational features as the amplifier circuit 210 according to the second embodiment will not be repeated.

The inductor 223 is an example of a third inductor. The inductor 223 is coupled between the output end of the carrier amplifier 211 and the radio-frequency output terminal 202. It is desirable that the phase difference of a radio-frequency signal between two ends of the inductor 223 be greater than the phase difference of a radio-frequency signal between two ends of the inductor 225.

The inductor 224 is an example of a fourth inductor. The inductor 224 is coupled between the output end of the peak amplifier 212 and the radio-frequency output terminal 202. It is desirable that the phase difference of a radio-frequency signal between two ends of the inductor 224 be greater than the phase difference of a radio-frequency signal between two ends of the inductor 225.

This configuration enables the inductor 225 to effectively shift the load impedance of the carrier amplifier 211.

The circuit component coupled between the output end of the carrier amplifier 211 and the radio-frequency output terminal 202 is not necessarily the inductor 223; the circuit component may be a first phase shifter circuit. The first phase shifter circuit is, for example, a circuit including the inductor 223 or a transmission line. It is desirable that the phase difference of a radio-frequency signal between two ends of the first phase shifter circuit be greater than the phase difference of a radio-frequency signal between two ends of the inductor 225.

This configuration enables the inductor 225 to effectively shift the load impedance of the carrier amplifier 211.

The circuit component coupled between the output end of the peak amplifier 212 and the radio-frequency output terminal 202 is not necessarily the inductor 224; the circuit component may be a second phase shifter circuit. The second phase shifter circuit is, for example, a circuit including the inductor 224 or a transmission line. It is desirable that the phase difference of a radio-frequency signal between two ends of the second phase shifter circuit be greater than the phase difference of a radio-frequency signal between two ends of the inductor 225.

It is desirable that: the first phase shifter circuit introduce a phase shift of the first phase amount to the first radio-frequency signal; the second phase shifter circuit introduce a phase shift of the second phase amount to the second radio-frequency signal; the first phase amount be equal to the second phase amount.

This configuration enables low-loss current combining at the radio-frequency output terminal 202, combining the first radio-frequency signal having travelled through the 90° hybrid 250, the carrier amplifier 211, the inductor 221, and the first phase shifter circuit and the second radio-frequency signal having travelled through the 90° hybrid 250, the peak amplifier 212, the capacitor 232, and the second phase shifter circuit.

It is desirable that based on the first phase shifter circuit being the inductor 223 provided in series in a path connecting the inductor 221 and the radio-frequency output terminal 202, and the second phase shifter circuit is the inductor 224 provided in series in a path connecting the capacitor 232 and the radio-frequency output terminal 202, the inductance of the inductor 223 be equal to the inductance of the inductor 224.

This configuration enables low-loss current combining at the radio-frequency output terminal 202, combining the first radio-frequency signal having travelled through the 90° hybrid 250, the carrier amplifier 211, and the inductors 221 and 223 and the second radio-frequency signal having travelled through the 90° hybrid 250, the peak amplifier 212, the capacitor 232, and the inductor 224.

The inductor 225 is an example of a fifth inductor. The inductor 225 is coupled between a path connecting the inductor 221 and the first phase shifter circuit (the inductor 223) and a path connecting the capacitor 232 and the second phase shifter circuit (the inductor 224). More specifically, one end of the inductor 225 is coupled to a node in the path connecting the inductor 221 and the first phase shifter circuit (the inductor 223), and the other end of the inductor 225 is coupled to a node in the path connecting the capacitor 232 and the second phase shifter circuit (the inductor 224).

The phase difference of radio-frequency signals between two ends of the inductor 225 is, for example, 45°. The phase difference of a radio-frequency signal between the two ends of the inductor 225 may be greater than 0° and smaller than 90°.

The circuit component coupled between the path connecting the inductor 221 and the first phase shifter circuit (the inductor 223) and the path connecting the capacitor 232 and the second phase shifter circuit (the inductor 224) is not necessarily the inductor 225; the circuit component may be a third phase shifter circuit. The third phase shifter circuit is, for example, a circuit including the inductor 225 or a ⅛ wavelength transmission line.

In the amplifier circuit 210A according to this modification, the carrier amplifier 211, the peak amplifier 212, the radio-frequency output terminal 202, the inductors 221, 222, 223, 224, and 225, and the capacitors 231 and 232 are constituent elements, but the 90° hybrid 250, the capacitors 233, 234, and 235, and the phase shift lines 251 and 252 are not necessarily included.

### 2.1.7 Operation Modes of Amplifier Circuit 210A

Because the amplifier circuit 210A according to the first modification additionally includes the first phase shifter circuit (the inductor 223), the second phase shifter circuit (the inductor 224), and the third phase shifter circuit (the inductor 225), the amplifier circuit 210A is able to shift the load impedance of the carrier amplifier 211 to a greater extent than the amplifier circuit 600 according to the second comparative example.

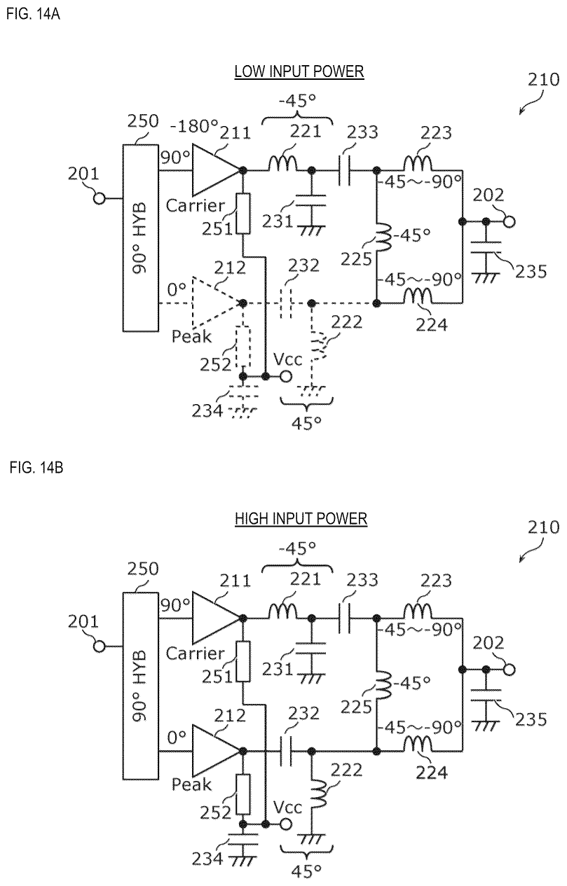

FIG. 14A is a circuit state diagram of the amplifier circuit 210A according to the first modification of the second embodiment at low input power. FIG. 14B is a circuit state diagram of the amplifier circuit 210A according to the first modification of the second embodiment at high input power.

In the amplifier circuit 210A, the 90° hybrid 250 introduces a phase difference of 90° between the first radio-frequency signal outputted from the carrier amplifier 211 and the second radio-frequency signal outputted from the peak amplifier 212. For example, the phase of the first radio-frequency signal outputted from the carrier amplifier 211 is 90°, and the phase of the second radio-frequency signal outputted from the peak amplifier 212 is 0°.

The low pass filter formed by the inductor 221 and the capacitor 231 delays the phase of the first radio-frequency signal by approximately 45°, and the inductor 223 further delays the phase of the first radio-frequency signal by X°. Consequently, the phase of the first radio-frequency signal at the radio-frequency output terminal 202 is (90−45−X°). The high pass filter formed by the capacitor 232 and the inductor 222 advances the phase of the second radio-frequency signal by approximately 45°, and the inductor 224 delays the phase of the second radio-frequency signal by X°. Consequently, the phase of the second radio-frequency signal at the radio-frequency output terminal 202 is (0+45−X°). Overall, the phase of the first radio-frequency signal and the phase of the second radio-frequency signal are aligned with each other at the radio-frequency output terminal 202, so that the current of the first radio-frequency signal and the current of the second radio-frequency signal are combined with low loss.

As illustrated in FIG. 14A, the peak amplifier 212 is turned off at low input power. As a result, the load impedance of the carrier amplifier 211 is relatively high. As such, this configuration increases efficiency of the amplifier circuit 210A in the input power region.

Next, as illustrated in FIG. 14B, the peak amplifier 212 is turned on at high input power. As a result, the load impedance of the carrier amplifier 211 is relatively low. This configuration enables low-distortion amplification in the high input power region, increasing peak power.

Overall, shifting the load impedance of the carrier amplifier 211 constituting the Doherty amplifier circuit 210A increases efficiency (back-off efficiency) in the region in which the peak amplifier 212 changes from the on-state to the off-state and also ensures peak power in the region in which the peak amplifier 212 is in the on-state.

Based on high input power being changed to low input power, the phase difference between the first radio-frequency signal outputted from the carrier amplifier 211 and the first radio-frequency signal reflected by the load and returned to the output end of the carrier amplifier 211 is the phase difference corresponding to the behavior of a signal traveling through the low pass filter and the inductor 225 and returning through the low pass filter and the inductor 225, that is, approximately 1800 ((45°+45°)×2). Thus, based on high input power being changed to low input power, the load impedance of the carrier amplifier 211 shifts in response to a 1800 phase shift (phase inversion). With this configuration, the amplifier circuit 210A according to this modification achieves a back-off level of 6 dB, which is the total of the back-off level based on the change of the peak amplifier 212 from the on-state to the off-state and the back-off level based on the shift of load impedance by phase inversion. This configuration improves efficiency (efficiency in the back-off region) at low input power.

In the case in which the phase rotation amount of the inductor 225 (the third phase shifter circuit) is not 45°, based on the phase rotation amount of the inductor 225 (the third phase shifter circuit) being between 0° and 90° exclusive, the amplifier circuit 210A achieves a back-off degree greater than 3 dB.

As a result, with modulation methods using relatively large PAPRs of about 6 dB, the amplifier circuit 210A according to this modification achieves high efficiency throughout a wider range of input power levels than the amplifier circuit 600 according to the second comparative example.

Based on the peak amplifier 212 being turned on, the inductor 225 functions as a balanced inductor between the carrier amplifier 211 and the peak amplifier 212. This configuration makes amplification stable at high input power.

### 2.1.8 Circuit Configuration of Amplifier Circuit 210B According to Second Modification

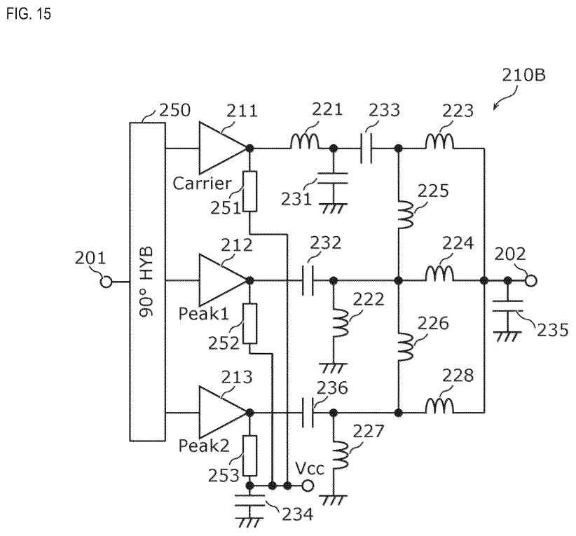

FIG. 15 is a circuit configuration diagram of an amplifier circuit 210B according to a second modification of the second embodiment. The amplifier circuit 210B according to this modification is configured as a three-way Doherty amplifier circuit including one carrier amplifier and two peak amplifiers. As illustrated in FIG. 15, the amplifier circuit 210B includes a carrier amplifier 211, peak amplifiers 212 and 213, a 90° hybrid 250, inductors 221, 222, 223, 224, 225, 226, 227, and 228, capacitors 231, 232, 233, 234, 235, and 236, phase shift lines 251, 252, and 253, a radio-frequency input terminal 201, and a radio-frequency output terminal 202. The amplifier circuit 210B according to this modification differs from the amplifier circuit 210A according to the first modification in that the peak amplifier 213, the inductors 226 to 228, and the capacitor 236 are additionally included. The following describes the amplifier circuit 210B according to this modification with a main focus on configurational features different from the amplifier circuit 210A according to the first modification, and descriptions of the same configurational features as the amplifier circuit 210A according to the first modification will not be repeated.

The carrier amplifier 211 is a Class-A (or Class-AB) amplifier circuit capable of amplification for all power levels of a first radio-frequency signal outputted from a first output end of the 90° hybrid 250. The carrier amplifier 211 is capable of highly efficient amplification especially in the low power output region and the middle power output region.

The peak amplifier 212 is a Class-C amplifier circuit capable of amplification for the middle and high power output regions of a second radio-frequency signal outputted from a second output end of the 90° hybrid 250. An amplifier transistor included in the peak amplifier 212 is configured to receive a bias voltage lower than a bias voltage applied to an amplifier transistor included in the carrier amplifier 211. As a result, as the power level of the second radio-frequency signal increases, the output impedance decreases. With this configuration, the peak amplifier 212 is able to provide low-distortion amplification in the middle and high power output regions.

The peak amplifier 213 is a Class-C amplifier circuit capable of amplification for the high power output region of a third radio-frequency signal outputted from a third output end of the 90° hybrid 250. An amplifier transistor included in the peak amplifier 213 is configured to receive a bias voltage lower than a bias voltage applied to an amplifier transistor included in the carrier amplifier 211. As a result, as the power level of the third radio-frequency signal increases, the output impedance decreases. With this configuration, the peak amplifier 213 is able to provide low-distortion amplification in the high power output region.

Each of the carrier amplifier 211 and the peak amplifiers 212 and 213 includes an amplifier transistor. The amplifier transistor is, for example, a bipolar transistor, such as an HBT, or a field-effect transistor, such as a MOSFET.

The input end of the 90° hybrid 250 is coupled to the radio-frequency input terminal 201. The first output end of the 90° hybrid 250 is coupled to the input end of the carrier amplifier 211, the second output end of the 90° hybrid 250 is coupled to the input end of the peak amplifier 212, and the third output end of the 90° hybrid 250 is coupled to the input end of the peak amplifier 213.

The capacitor 236 is provided in series in a third output path connecting the output end of the peak amplifier 213 and the inductor 228. The inductor 227 is coupled between the third output path and the ground. The capacitor 236 and the inductor 227 form a high pass filter that introduces a phase advance of approximately 45° to radio-frequency signals.

The inductor 228 is coupled between the output end of the peak amplifier 213 and the radio-frequency output terminal 202. It is desirable that the phase difference of a radio-frequency signal between two ends of the inductor 228 be greater than the phase difference of a radio-frequency signal between two ends of the inductor 226.

The circuit component coupled between the output end of the peak amplifier 213 and the radio-frequency output terminal 202 is not necessarily the inductor 228; the circuit component may be a sixth phase shifter circuit. The sixth phase shifter circuit is, for example, a circuit including the inductor 228 or a transmission line. It is desirable that the phase difference of a radio-frequency signal between two ends of the sixth phase shifter circuit be greater than the phase difference of a radio-frequency signal between two ends of the inductor 226.

Based on the first phase shifter circuit (the inductor 223) introducing a phase shift of a first phase amount to the first radio-frequency signal, the second phase shifter circuit (the inductor 224) introduces a phase shift of a second phase amount to the second radio-frequency signal, and the sixth phase shifter circuit (the inductor 228) introduces a phase shift of a sixth phase amount to the third radio-frequency signal, it is desirable that the first phase amount, the second phase amount, and the sixth phase amount be equal to each other.

This configuration enables low-loss current combining at the radio-frequency output terminal 202, combining the first radio-frequency signal having travelled through the 90° hybrid 250, the carrier amplifier 211, the inductor 221, and the first phase shifter circuit, the second radio-frequency signal having travelled through the 90° hybrid 250, the peak amplifier 212, the capacitor 232, and the second phase shifter circuit, and the third radio-frequency signal having travelled through the 90° hybrid 250, the peak amplifier 213, the capacitor 236, and the sixth phase shifter circuit.

The inductor 226 is coupled between a path connecting the capacitor 232 and the second phase shifter circuit (the inductor 224) and a path connecting the capacitor 236 and the sixth phase shifter circuit (the inductor 228). More specifically, one end of the inductor 226 is coupled to a node in the path connecting the capacitor 232 and the second phase shifter circuit (the inductor 224), and the other end of the inductor 226 is coupled to a node in the path connecting the capacitor 236 and the sixth phase shifter circuit (the inductor 228).

The phase difference of radio-frequency signals between two ends of the inductor 226 is, for example, 45°. The phase difference of a radio-frequency signal between the two ends of the inductor 226 may be greater than 0° and smaller than 90°.

The circuit component coupled between the path connecting the capacitor 232 and the second phase shifter circuit (the inductor 224) and the path connecting the capacitor 236 and the sixth phase shifter circuit (the inductor 228) is not necessarily the inductor 226; the circuit component may be a seventh phase shifter circuit. The seventh phase shifter circuit is, for example, a circuit including the inductor 226 or a ⅛ wavelength transmission line.

In the amplifier circuit 210B according to this modification, the carrier amplifier 211, the peak amplifiers 212 and 213, the radio-frequency output terminal 202, the inductors 221, 222, 223, 224, 225, 226, 227 and 228, and the capacitors 231, 232, and 236 are constituent elements, but the 90° hybrid 250, the capacitors 233, 234, and 235, and the phase shift lines 251, 252, and 253 are not necessarily included.

The peak amplifiers 212 and 213 are turned off at low input power. As a result, the load impedance of the carrier amplifier 211 is relatively high. As such, this configuration increases efficiency of the amplifier circuit 210B in the low input power region.

The peak amplifiers 212 and 213 are turned on at high input power. As a result, the load impedance of the carrier amplifier 211 is relatively low. This configuration enables low-distortion amplification in the high input power region, increasing peak power.

At middle input power, the peak amplifier 213 is turned off, and the peak amplifier 212 is turned on. As a result, the load impedance of the carrier amplifier 211 is lower than the load impedance at low input power and higher than the load impedance at high input power. As such, this configuration increases efficiency of the amplifier circuit 210B in the middle input power region.

Thus, based on high input power being changed to middle input power and low input power, the load impedance of the carrier amplifier 211 shifts in response to an approximately 1800 phase shift (phase inversion). With this configuration, the amplifier circuit 210B according to this modification achieves a back-off level of 9.5 dB, which is the total of the back-off level based on the change of the peak amplifiers 212 and 213 from the on-state to the off-state and the back-off level based on the shift of load impedance by phase inversion. This configuration improves efficiency (efficiency in the back-off region) at low input power and middle input power.

In the case in which the phase rotation amount of the inductor 225 (the third phase shifter circuit) and the inductor 226 (the seventh phase shifter circuit) is not 45°, based on the phase rotation amount of the inductor 225 (the third phase shifter circuit) and the inductor 226 (the seventh phase shifter circuit) being between 0° and 90° exclusive, the amplifier circuit 210B achieves a back-off degree greater than 3 dB.

As a result, with modulation methods using relatively large PAPRs of 6 dB or higher, the amplifier circuit 210B according to this modification achieves high efficiency throughout a wider range of input power levels than the amplifier circuits according to the second comparative example and the first modification.

Based on the peak amplifier 212 being turned on, the inductor 225 functions as a balanced inductor between the carrier amplifier 211 and the peak amplifier 212. This configuration makes amplification stable at middle input power and high input power. Based on the peak amplifiers 212 and 213 being turned on, the inductor 226 functions as a balanced inductor between the peak amplifiers 212 and 213. This configuration makes amplification stable at high input power.

### 2.1.9 Relationship Between Back-Off Level and Efficiency

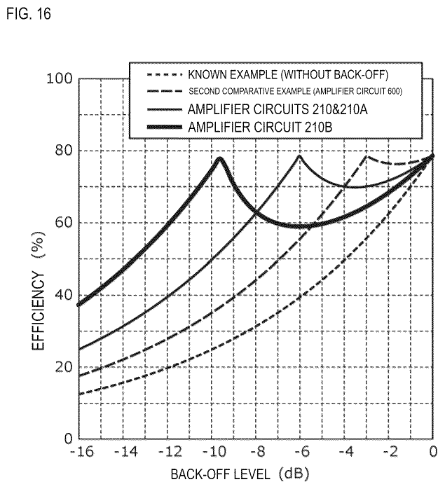

FIG. 16 is a graph comparing the efficiency characteristics of the amplifier circuits of the second embodiment, an amplifier circuit of a known example, and the amplifier circuit of the comparative example. The drawing illustrates (1) the efficiency characteristic of a known amplifier circuit (without back-off) including one amplifier, (2) the efficiency characteristic of the amplifier circuit 600 according to the second comparative example, (3) the efficiency characteristic of the amplifier circuit 210 according to the second embodiment and the amplifier circuit 210A according to the first modification, and (4) the efficiency characteristic of the amplifier circuit 210B according to the second modification.

The amplifier circuit 210 according to the second embodiment and the amplifier circuit 210A according to the first modification achieve increased efficiency in the 6 dB back-off region, as compared to the amplifier circuits according to the known example and comparative example. The amplifier circuit 210B according to the second modification achieves increased efficiency in the 9.5 dB back-off region, as compared to the amplifier circuits according to the known example and comparative example.

### 2.2 Component Arrangement of Amplifier Circuit and Radio-Frequency Circuit

Next, a component arrangement of the amplifier circuit 210A and a radio-frequency circuit 5A according to the first modification will be described.

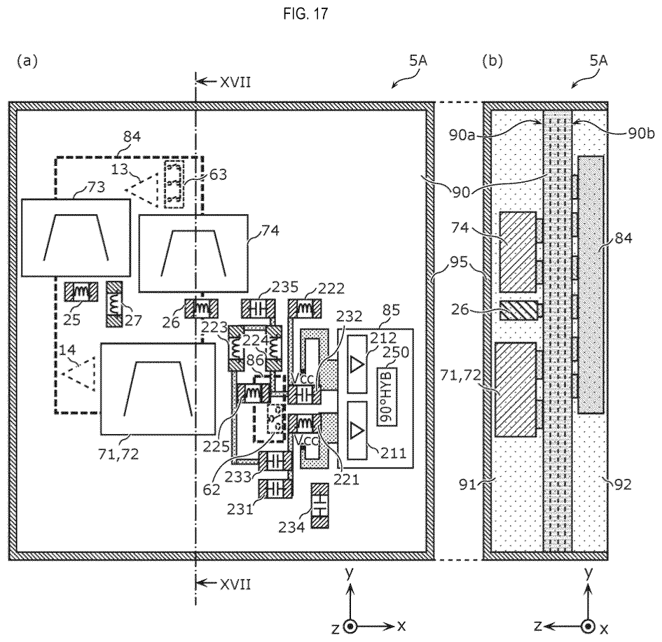

FIG. 17 provides plan and sectional views of the radio-frequency circuit 5A according to the first modification. In FIG. 17, (a) is a cutaway view of an arrangement of circuit components based on a major surface 90a of a module substrate 90 being viewed from the front side in the positive direction of the z axis. In FIG. 17, (b) is a sectional view taken along line XVII-XVII in (a) of FIG. 17. In FIG. 17, some wire lines connecting the module substrate 90 and the circuit components are not illustrated.

In the radio-frequency circuit 5A, the amplifier circuit 210 from the radio-frequency circuit 5 illustrated in FIG. 10 is replaced with the amplifier circuit 210A. The radio-frequency circuit 5A further includes the module substrate 90, resin members 91 and 92, a shield electrode layer 95, and multiple external connection terminals 150.

The module substrate 90, the resin members 91 and 92, the shield electrode layer 95, and the external connection terminals 150 are the same configuration elements as the first embodiment illustrated in FIG. 9, and descriptions thereof will not be repeated.

As illustrated in FIG. 17, the carrier amplifier 211 and the peak amplifier 212, the 90° hybrid 250, the filters 71 to 74, the inductors 25 to 27 and 221 to 225, and the capacitors 231 to 235 are disposed at the major surface 90a of the module substrate 90.

The low-noise amplifiers 13 and 14 and the switches 62 and 63 are disposed at the major surface 90b of the module substrate 90.

With this arrangement, the circuit components are disposed separately at the major surface 90a or 90b of the module substrate 90. This arrangement thus reduces the size of the radio-frequency circuit 5A.

The carrier amplifier 211, the peak amplifier 212, and the 90° hybrid 250 are included in a semiconductor IC 85. The low-noise amplifiers 13 and 14 and the switch 63 are included in a semiconductor IC 84. The switch 62 is included in a semiconductor IC 86.

With this arrangement, the carrier amplifier 211 and the peak amplifier 212 are integrated into one chip, the low-noise amplifiers 13 and 14 and the switch 63 are integrated into one chip, and the switch 62 is integrated into one chip. This arrangement thus reduces the size of the radio-frequency circuit 5A.

The semiconductor ICs 84, 85, and 86 may be made using, for example, CMOS. Specifically, the semiconductor ICs 84, 85, and 86 may be manufactured using an SOI process. The semiconductor ICs may be made of at least one of GaAs, SiGe, and GaN. The semiconductor material of the semiconductor ICs 84 to 86 is not limited to the materials presented above.

The radio-frequency circuit 5 according to the second embodiment has the same component arrangement as the radio-frequency circuit 5A except that the inductor 225 is not provided.

### 2.3 Effects

As described above, the amplifier circuit 210 according to the second embodiment includes the carrier amplifier 211 and the peak amplifier 212, the radio-frequency output terminal 202, the first phase shifter circuit coupled between the output end of the carrier amplifier 211 and the radio-frequency output terminal 202, the second phase shifter circuit coupled between the output end of the peak amplifier 212 and the radio-frequency output terminal 202, the inductor 221 provided in series in the first output path connecting the output end of the carrier amplifier 211 and the first phase shifter circuit, the capacitor 231 coupled between the first output path and the ground, the capacitor 232 provided in series in the second output path connecting the output end of the peak amplifier 212 and the second phase shifter circuit, and the inductor 222 coupled between the second output path and the ground. The first phase shifter circuit includes the inductor 223. The second phase shifter circuit includes the inductor 224.

With this configuration, shifting the load impedance of the carrier amplifier 211 increases efficiency (back-off efficiency) in the region in which the peak amplifier 212 changes from the on-state to the off-state and also ensures peak power in the region in which the peak amplifier 212 is in the on-state. Further, based on high input power being changed to low input power, the load impedance of the carrier amplifier 211 shifts in response to a 1800 phase shift (phase inversion). This configuration achieves a back-off level of 6 dB, which is the total of the back-off level based on the change of the peak amplifier 212 from the on-state to the off-state and the back-off level based on the shift of load impedance by phase inversion. This configuration improves efficiency (efficiency in the back-off region) at low input power. As such, the amplifier circuit 210 having a highly efficient amplification characteristic is provided.

In an example, in the amplifier circuit 210, the first phase shifter circuit introduces a phase shift of the first phase amount to a radio-frequency signal; the second phase shifter circuit introduces a phase shift of the second phase amount to a radio-frequency signal; the first phase amount is equal to the second phase amount.

This configuration enables low-loss current combining at the radio-frequency output terminal 202, combining the first radio-frequency signal having travelled through the carrier amplifier 211, the inductor 221, and the first phase shifter circuit and the second radio-frequency signal having travelled through the peak amplifier 212, the capacitor 232, and the second phase shifter circuit.

In an example, the inductor 223 is provided in series in the path connecting the inductor 221 and the radio-frequency output terminal 202; the inductor 224 is provided in series in the path connecting the capacitor 232 and the radio-frequency output terminal 202; the inductance of the inductor 223 is equal to the inductance of the inductor 224.

This configuration enables low-loss current combining at the radio-frequency output terminal 202, combining the first radio-frequency signal having travelled through the carrier amplifier 211, the inductors 221 and 223 and the second radio-frequency signal having travelled through the peak amplifier 212, the capacitor 232, and the inductor 224.

In an example, the amplifier circuit 210A according to the first modification further includes the third phase shifter circuit coupled between the path connecting the inductor 221 and the first phase shifter circuit and the path connecting the capacitor 232 and the second phase shifter circuit. The third phase shifter circuit includes the inductor 225.

With this configuration, shifting the load impedance of the carrier amplifier 211 increases efficiency (back-off efficiency) in the region in which the peak amplifier 212 changes from the on-state to the off-state and also ensures peak power in the region in which the peak amplifier 212 is in the on-state.

Further, based on high input power being changed to low input power, the load impedance of the carrier amplifier 211 shifts in response to an approximately 1800 phase shift (phase inversion). This configuration achieves a back-off level of 6 dB, which is the total of the back-off level based on the change of the peak amplifier 212 from the on-state to the off-state and the back-off level based on the shift of load impedance by phase inversion. This configuration improves efficiency (efficiency in the back-off region) at low input power. Based on the peak amplifier 212 being turned on, the inductor 225 functions as a balanced inductor between the carrier amplifier 211 and the peak amplifier 212. This configuration makes amplification stable at high input power.

In an example, in the amplifier circuit 210A according to the first modification, the first phase shifter circuit introduces a phase shift of the first phase amount to a radio-frequency signal; the second phase shifter circuit introduces a phase shift of the second phase amount to a radio-frequency signal; the third phase shifter circuit introduces a phase shift of the third phase amount to a radio-frequency signal. Each of the first phase amount and the second phase amount is greater than the third phase amount.

This configuration enables the third phase shifter circuit to effectively shift the load impedance of the carrier amplifier 211.

The amplifier circuit 210 according to the second embodiment includes the carrier amplifier 211 and the peak amplifier 212, the radio-frequency output terminal 202, the first phase shifter circuit coupled between the output end of the carrier amplifier 211 and the radio-frequency output terminal 202, the second phase shifter circuit coupled between the output end of the peak amplifier 212 and the radio-frequency output terminal 202, the fourth phase shifter circuit coupled to the output end of the carrier amplifier 211 and the first phase shifter circuit and configured to introduce a phase shift of the fourth phase amount to a radio-frequency signal, and the fifth phase shifter circuit coupled to the output end of the peak amplifier 212 and the second phase shifter circuit and configured to introduce a phase shift of the fifth phase amount to a radio-frequency signal, the fifth phase amount being different from the fourth phase amount by 90°. The first phase shifter circuit is configured to have the same phase rotation amount as the second phase shifter circuit.

With this configuration, shifting the load impedance of the carrier amplifier 211 increases efficiency (back-off efficiency) in the region in which the peak amplifier 212 changes from the on-state to the off-state and also ensures peak power in the region in which the peak amplifier 212 is in the on-state. Further, based on high input power being changed to low input power, the load impedance of the carrier amplifier 211 shifts in response to a 1800 phase shift (phase inversion). This configuration achieves a back-off level of 6 dB, which is the total of the back-off level based on the change of the peak amplifier 212 from the on-state to the off-state and the back-off level based on the shift of load impedance by phase inversion. This configuration improves efficiency (efficiency in the back-off region) at low input power. As such, the amplifier circuit 210 having a highly efficient amplification characteristic is provided.

The communication device 7 according to the second embodiment includes the RFIC 6 configured to process radio-frequency signals and the amplifier circuit 210 configured to transfer radio-frequency signals between the RFIC 6 and the antenna 2.

This configuration enables the communication device 7 to achieve the effects of the amplifier circuit 210.

### OTHER EMBODIMENTS

The amplifier circuit, radio-frequency circuit, communication device, and amplification method according to the embodiments of the present disclosure have been described using the embodiments and modifications. However, the amplifier circuit, radio-frequency circuit, communication device, and amplification method according to the embodiments of the present disclosure are not limited to the embodiments and modifications described above. The present disclosure also embraces other embodiments implemented as any combination of the constituent elements of the embodiments and modifications, other modifications obtained by making various modifications to the embodiment that occur to those skilled in the art without departing from the scope of the present disclosure, and various hardware devices including the amplifier circuit, radio-frequency circuit, or communication device according to the present disclosure.

For example, in the amplifier circuit, radio-frequency circuit, and communication device according to the embodiments and modifications described above, other circuit elements and wire lines may be inserted in the paths connecting the circuit elements and signal paths that are illustrated in the drawings.

The following describes the features of the amplifier circuit, radio-frequency circuit, communication device, and amplification method described based on the embodiments.

<1>

An amplifier circuit comprising:
a first amplifier and a second amplifier;
an output terminal;
a first phase shifter circuit coupled between an output end of the first amplifier and the output terminal;
a second phase shifter circuit coupled between an output end of the second amplifier and the output terminal;
a first inductor provided in series in a first output path connecting the output end of the first amplifier and the first phase shifter circuit;
a first capacitor coupled between the first output path and ground;
a second capacitor provided in series in a second output path connecting the output end of the second amplifier and the second phase shifter circuit;
a second inductor coupled between the second output path and ground; and
a first circuit coupled between a first path connecting the first inductor and the first phase shifter circuit and a second path connecting the second capacitor and the second phase shifter circuit,
the first circuit including
   a first resistor having one end configured to be coupled to the first path and another end configured to be coupled to the second path, and
   a first switch configured to selectively couple the first path and the second path to each other via the first resistor or without using the first resistor.

<2>

An amplifier circuit comprising:
a first amplifier and a second amplifier;
an output terminal;
a first phase shifter circuit coupled between an output end of the first amplifier and the output terminal;
a second phase shifter circuit coupled between an output end of the second amplifier and the output terminal;
a third phase shifter circuit coupled to the output end of the first amplifier and the first phase shifter circuit, the third phase shifter circuit being configured to introduce a phase shift of a first phase amount to a radio-frequency signal;
a fourth phase shifter circuit coupled to the output end of the second amplifier and the second phase shifter circuit, the fourth phase shifter circuit being configured to introduce a phase shift of a second phase amount to a radio-frequency signal, the second phase amount being different from the first phase amount by 90°; and
a first circuit coupled between a first path connecting the third phase shifter circuit and the first phase shifter circuit and a second path connecting the fourth phase shifter circuit and the second phase shifter circuit,
the first circuit including
   a first resistor having one end configured to be coupled to the first path and another end configured to be coupled to the second path, and
   a first switch configured to selectively couple the first path and the second path to each other via the first resistor or without using the first resistor.

<3>

The amplifier circuit according to <1> or <2>, wherein
the first switch has a common terminal, a first selection terminal, and a second selection terminal,
the first resistor has a first end and a second end,
the first end is coupled to the first selection terminal,
the common terminal is coupled to one of the first path and the second path,
the second end is coupled to another of the first path and the second path, and
the second selection terminal is coupled to the other of the first path and the second path without using any resistor.

<4>

The amplifier circuit according to <3>, wherein
the second selection terminal and the other of the first path and the second path are short-circuited.

<5>

The amplifier circuit according to any of <1> to <4>, wherein
based on the first path and the second path being short-circuited, the first amplifier operates in Class AB, and the second amplifier operates in Class C, and
based on the first path and the second path being not short-circuited, and the first resistor is coupled to the first path and the second path, the first amplifier operates in Class AB, and the second amplifier operates in Class AB.

<6>

The amplifier circuit according to any of <1> to <4>, wherein
based on a low power mode being applied to the amplifier circuit, the first path and the second path are not short-circuited, and the first resistor is coupled to the first path and the second path, and
based on a high power mode being applied to the amplifier circuit, the first path and the second path are short-circuited.

<7>

The amplifier circuit according to <4>, wherein
the first circuit further includes a first circuit element that is an inductor or capacitor,
the first switch further includes a third selection terminal,
one end of the first circuit element is coupled to the third selection terminal, and
another end of the first circuit element is coupled to the other of the first path and the second path.

<8>

The amplifier circuit according to <7>, wherein
based on the first path and the second path being short-circuited, the first amplifier operates in Class AB, and the second amplifier operates in Class C, and
based on the first circuit element being coupled to the first path and the second path, the first amplifier operates in Class AB, and the second amplifier operates in Class C, and
based on the first resistor being coupled to the first path and the second path, the first amplifier operates in Class AB, and the second amplifier operates in Class AB.

<9>

The amplifier circuit according to <7>, wherein
based on the amplifier circuit operating in Power Class 1.5, the first circuit element is coupled to the first path and the second path,
based on the amplifier circuit operating in Power Class 2, the first path and the second path are short-circuited, and
based on the amplifier circuit operating in Power Class 3, the first resistor is coupled to the first path and the second path.

<10>

The amplifier circuit according to <7>, wherein
based on a low power mode being applied to the amplifier circuit, the first resistor is coupled to the first path and the second path.

<11>

An amplifier circuit comprising:
a carrier amplifier and a peak amplifier;
an output terminal;
a first phase shifter circuit coupled between an output end of the carrier amplifier and the output terminal;
a second phase shifter circuit coupled between an output end of the peak amplifier and the output terminal;
a first inductor provided in series in a first output path connecting the output end of the carrier amplifier and the first phase shifter circuit;
a first capacitor coupled between the first output path and ground;
a second capacitor provided in series in a second output path connecting the output end of the peak amplifier and the second phase shifter circuit; and
a second inductor coupled between the second output path and ground, wherein
the first phase shifter circuit includes a third inductor, and
the second phase shifter circuit includes a fourth inductor.

<12>

The amplifier circuit according to <11>, wherein
the first phase shifter circuit is configured to introduce a phase shift of a first phase amount to a radio-frequency signal, and
the second phase shifter circuit is configured to introduce a phase shift of a second phase amount to a radio-frequency signal, the second phase amount being equal to the first phase amount.

<13>

The amplifier circuit according to <11> or <12>, wherein
the third inductor is provided in series in a path connecting the first inductor and the output terminal,
the fourth inductor is provided in series in a path connecting the second capacitor and the output terminal, and
an inductance of the third inductor is equal to an inductance of the fourth inductor.

<14>

The amplifier circuit according to any of <11> to <13>, further comprising
a third phase shifter circuit coupled between a path connecting the first inductor and the first phase shifter circuit and a path connecting the second capacitor and the second phase shifter circuit,
the third phase shifter circuit including a fifth inductor.

<15>

The amplifier circuit according to <14>, wherein
the first phase shifter circuit is configured to introduce a phase shift of a first phase amount to a radio-frequency signal,
the second phase shifter circuit is configured to introduce a phase shift of a second phase amount to a radio-frequency signal,
the third phase shifter circuit is configured to introduce a phase shift of a third phase amount to a radio-frequency signal, and
each of the first phase amount and the second phase amount is greater than the third phase amount.

<16>

An amplifier circuit comprising:
a carrier amplifier and a peak amplifier;
an output terminal;
a first phase shifter circuit coupled between an output end of the carrier amplifier and the output terminal;
a second phase shifter circuit coupled between an output end of the peak amplifier and the output terminal;
a fourth phase shifter circuit coupled to the output end of the carrier amplifier and the first phase shifter circuit, the fourth phase shifter circuit being configured to introduce a phase shift of a fourth phase amount to a radio-frequency signal; and
a fifth phase shifter circuit coupled to the output end of the peak amplifier and the second phase shifter circuit, the fifth phase shifter circuit being configured to introduce a phase shift of a fifth phase amount to a radio-frequency signal, the fifth phase amount being different from the fourth phase amount by 90°, wherein
the first phase shifter circuit is configured to have the same phase rotation amount as the second phase shifter circuit.

<17>

A radio-frequency circuit comprising:
the amplifier circuit according to any of <1> to <10>;
a first filter having a pass band that includes at least a portion of a first band;
a second filter having a pass band that includes at least a portion of a second band; and
a second switch configured to selectively couple the output terminal to the first filter or the second filter.

<18>

The radio-frequency circuit according to <17>, further comprising:
a module substrate having a first major surface and a second major surface that are opposite to each other; and
an external connection terminal disposed at the second major surface, wherein
the first amplifier and the second amplifier are disposed at the first major surface, and
the first switch and the second switch are disposed at the second major surface.

<19>

The radio-frequency circuit according to <18>, wherein
the first switch and the second switch are included in a first semiconductor integrated circuit (IC).

<20>

The radio-frequency circuit according to <19>, wherein
the first resistor is disposed at the first major surface, and
based on the module substrate being viewed in plan view, the first resistor and the first semiconductor IC at least partially overlap.

<21>

A communication device comprising:
a signal processing circuit configured to process a radio-frequency signal; and
the amplifier circuit according to any of <1> to <16>, the amplifier circuit being configured to transfer the radio-frequency signal between the signal processing circuit and an antenna.

<22>

An amplification method comprising:
aligning the phase of a first radio-frequency signal amplified by a first amplifier and the phase of a second radio-frequency signal amplified by a second amplifier with each other;
in a first mode, coupling a first path that transfers the phase-aligned first radio-frequency signal and a second path that transfers the phase-aligned second radio-frequency signal to each other via a first resistor and combining the first radio-frequency signal and the second radio-frequency signal; and
in a second mode, coupling a first path that transfers the phase-aligned first radio-frequency signal and a second path that transfers the phase-aligned second radio-frequency signal to each other without using the first resistor and combining the first radio-frequency signal and the second radio-frequency signal.

The present disclosure can be used as an amplifier circuit and a communication device provided at the front-end in a wide variety of communication devices such as mobile phones.

What is claimed is:

1. An amplifier circuit comprising:
a first amplifier and a second amplifier;
an output terminal;
a first phase shifter circuit coupled between an output end of the first amplifier and the output terminal;
a second phase shifter circuit coupled between an output end of the second amplifier and the output terminal;
a first inductor provided in series in a first output path connecting the output end of the first amplifier and the first phase shifter circuit;
a first capacitor coupled between the first output path and ground;
a second capacitor provided in series in a second output path connecting the output end of the second amplifier and the second phase shifter circuit;
a second inductor coupled between the second output path and ground; and
a first circuit coupled between a first path connecting the first inductor and the first phase shifter circuit and a second path connecting the second capacitor and the second phase shifter circuit,
the first circuit including
a first resistor having one end configured to be coupled to the first path and another end configured to be coupled to the second path, and
a first switch configured to selectively couple the first path and the second path to each other via the first resistor or without using the first resistor.

2. An amplifier circuit comprising:
a first amplifier and a second amplifier;
an output terminal;
a first phase shifter circuit coupled between an output end of the first amplifier and the output terminal;
a second phase shifter circuit coupled between an output end of the second amplifier and the output terminal;
a third phase shifter circuit coupled to the output end of the first amplifier and the first phase shifter circuit, the third phase shifter circuit being configured to introduce a phase shift of a first phase amount to a radio-frequency signal;
a fourth phase shifter circuit coupled to the output end of the second amplifier and the second phase shifter circuit, the fourth phase shifter circuit being configured to introduce a phase shift of a second phase amount to a radio-frequency signal, the second phase amount being different from the first phase amount by 90°; and
a first circuit coupled between a first path connecting the third phase shifter circuit and the first phase shifter circuit and a second path connecting the fourth phase shifter circuit and the second phase shifter circuit,
the first circuit including
a first resistor having one end configured to be coupled to the first path and another end configured to be coupled to the second path, and
a first switch configured to selectively couple the first path and the second path to each other via the first resistor or without using the first resistor.

3. The amplifier circuit according to claim 2, wherein
the first switch has a common terminal, a first selection terminal, and a second selection terminal,
the first resistor has a first end and a second end,
the first end is coupled to the first selection terminal,
the common terminal is coupled to one of the first path and the second path,
the second end is coupled to another of the first path and the second path, and
the second selection terminal is coupled to the other of the first path and the second path without using any resistor.

4. The amplifier circuit according to claim 3, wherein
the second selection terminal and the other of the first path and the second path are short-circuited.

5. The amplifier circuit according to claim 2, wherein
based on the first path and the second path being short-circuited, the first amplifier operates in Class AB, and the second amplifier operates in Class C, and
based on the first path and the second path being not short-circuited, and the first resistor is coupled to the first path and the second path, the first amplifier operates in Class AB, and the second amplifier operates in Class AB.

6. The amplifier circuit according to claim 2, wherein
based on a low power mode being applied to the amplifier circuit, the first path and the second path are not short-circuited, and the first resistor is coupled to the first path and the second path, and
based on a high power mode being applied to the amplifier circuit, the first path and the second path are short-circuited.

7. The amplifier circuit according to claim 4, wherein
the first circuit further includes a first circuit element that is an inductor or capacitor,
the first switch further includes a third selection terminal,
one end of the first circuit element is coupled to the third selection terminal, and
another end of the first circuit element is coupled to the other of the first path and the second path.

8. The amplifier circuit according to claim 7, wherein
based on the first path and the second path being short-circuited, the first amplifier operates in Class AB, and the second amplifier operates in Class C,
based on the first circuit element being coupled to the first path and the second path, the first amplifier operates in Class AB, and the second amplifier operates in Class C, and
based on the first resistor being coupled to the first path and the second path, the first amplifier operates in Class AB, and the second amplifier operates in Class AB.

9. The amplifier circuit according to claim 7, wherein
based on the amplifier circuit operating in Power Class 1.5, the first circuit element is coupled to the first path and the second path,
based on the amplifier circuit operating in Power Class 2, the first path and the second path are short-circuited, and
based on the amplifier circuit operating in Power Class 3, the first resistor is coupled to the first path and the second path.

10. The amplifier circuit according to claim 7, wherein
based on a low power mode being applied to the amplifier circuit, the first resistor is coupled to the first path and the second path.

11. An amplifier circuit comprising:
a carrier amplifier and a peak amplifier;
an output terminal;
a first phase shifter circuit coupled between an output end of the carrier amplifier and the output terminal;
a second phase shifter circuit coupled between an output end of the peak amplifier and the output terminal;
a first inductor provided in series in a first output path connecting the output end of the carrier amplifier and the first phase shifter circuit;
a first capacitor coupled between the first output path and ground;
a second capacitor provided in series in a second output path connecting the output end of the peak amplifier and the second phase shifter circuit; and
a second inductor coupled between the second output path and ground, wherein
the first phase shifter circuit includes a third inductor, and
the second phase shifter circuit includes a fourth inductor.

12. The amplifier circuit according to claim 11, wherein
the first phase shifter circuit is configured to introduce a phase shift of a first phase amount to a radio-frequency signal, and
the second phase shifter circuit is configured to introduce a phase shift of a second phase amount to a radio-frequency signal, the second phase amount being equal to the first phase amount.

13. The amplifier circuit according to claim 11, wherein
the third inductor is provided in series in a path connecting the first inductor and the output terminal,
the fourth inductor is provided in series in a path connecting the second capacitor and the output terminal, and
an inductance of the third inductor is equal to an inductance of the fourth inductor.

14. The amplifier circuit according to claim 13, further comprising
a third phase shifter circuit coupled between a path connecting the first inductor and the first phase shifter circuit and a path connecting the second capacitor and the second phase shifter circuit,
the third phase shifter circuit including a fifth inductor.

15. The amplifier circuit according to claim 14, wherein
the first phase shifter circuit is configured to introduce a phase shift of a first phase amount to a radio-frequency signal,
the second phase shifter circuit is configured to introduce a phase shift of a second phase amount to a radio-frequency signal,
the third phase shifter circuit is configured to introduce a phase shift of a third phase amount to a radio-frequency signal, and
each of the first phase amount and the second phase amount is greater than the third phase amount.

16. An amplifier circuit comprising:
a carrier amplifier and a peak amplifier;
an output terminal;
a first phase shifter circuit coupled between an output end of the carrier amplifier and the output terminal;
a second phase shifter circuit coupled between an output end of the peak amplifier and the output terminal;
a fourth phase shifter circuit coupled to the output end of the carrier amplifier and the first phase shifter circuit, the fourth phase shifter circuit being configured to introduce a phase shift of a fourth phase amount to a radio-frequency signal; and
a fifth phase shifter circuit coupled to the output end of the peak amplifier and the second phase shifter circuit, the fifth phase shifter circuit being configured to introduce a phase shift of a fifth phase amount to a radio-frequency signal, the fifth phase amount being different from the fourth phase amount by 90°, wherein
the first phase shifter circuit is configured to have the same phase rotation amount as the second phase shifter circuit.

17. A radio-frequency circuit comprising:
the amplifier circuit according to claim 1;
a first filter having a pass band that includes at least a portion of a first band;
a second filter having a pass band that includes at least a portion of a second band; and
a second switch configured to selectively couple the output terminal to the first filter or the second filter.

18. The radio-frequency circuit according to claim 17, further comprising:
a module substrate having a first major surface and a second major surface that are opposite to each other; and
an external connection terminal disposed at the second major surface, wherein
the first amplifier and the second amplifier are disposed at the first major surface, and
the first switch and the second switch are disposed at the second major surface.

19. The radio-frequency circuit according to claim 18, wherein
the first switch and the second switch are included in a first semiconductor integrated circuit (IC).

20. The radio-frequency circuit according to claim 19, wherein
the first resistor is disposed at the first major surface, and
based on the module substrate being viewed in plan view, the first resistor and the first semiconductor IC at least partially overlap.
